(19) United States
(12) Patent Application Publication
(10) Pub. No.: US 2022/0299759 A1
(43) Pub. Date: Sep. 22, 2022

(54) LIGHT DEFLECTOR, IMAGE PROJECTION APPARATUS, AND DISTANCE-MEASURING APPARATUS

(71) Applicants: Tetsuroh TATEBE, Osaka (JP); Masami SETO, Osaka (JP)

(72) Inventors: Tetsuroh TATEBE, Osaka (JP); Masami SETO, Osaka (JP)

(21) Appl. No.: 17/693,415

(22) Filed: Mar. 14, 2022

(30) Foreign Application Priority Data
Mar. 18, 2021 (JP) 2021-045177

(51) Int. Cl. G02B 26/10; G02B 26/08; G02B 27/01

(52) U.S. Cl. CPC G02B 26/101; G02B 26/0858; G02B 27/0172; G02B 2027/0178

(57) ABSTRACT

A light deflector includes a movable part, a pair of beams to make the movable part swing or oscillate, a supporting portion supporting the pair of beams, and circuitry to obtain information about swing or oscillation of the movable part. In the light deflector, each one of the pair of beams includes a first piezoelectric member to which a first voltage is input and a second piezoelectric member configured to generate a second voltage, and the supporting portion includes a third piezoelectric member configured to generate a third voltage. In the light deflector, the first piezoelectric member is configured to deform the pair of beams based on the first voltage to make the movable part swing or oscillate, and the circuitry is configured to obtain the information about the swing or oscillation of the movable part based on information about the second voltage and information about the third voltage.

### CROSS-REFERENCE TO RELATED APPLICATION

This patent application is based on and claims priority pursuant to 35 U.S.C. § 119(a) to Japanese Patent Application No. 2021-045177, filed on Mar. 18, 2021, in the Japan Patent Office, the entire disclosure of which is hereby incorporated by reference herein.

### BACKGROUND

### Technical Field

Embodiments of the present disclosure relate to a light deflector, an image projection apparatus, a heads-up display, a laser headlamp, a head-mounted display, a distance-measuring apparatus, and a mobile object.

### Background Art

Currently, micromachining technology to which semiconductor manufacturing technology is applied is developed, and the development of a micro-electromechanical systems (MEMS) device as a light-deflector that is manufactured by performing micromachining or fine patterning for silicon or glass is in progress,

For the purposes of detecting vibration in biaxial directions of a movable part such as a mirror unit, a configuration or structure is known in the art that includes a first piezoelectric actuator that makes the movable part swing or oscillate around the first axis and a second piezoelectric actuator that swings a first support part surrounding the movable part around the second axis. In such a known configuration or structure, a detection piezoelectric element that detects the first vibration caused by the first piezoelectric actuator and the second vibration caused by the second piezoelectric actuator is arranged on the first support part.

### SUMMARY

Embodiments of the present disclosure described herein provide a light deflector, an image projection apparatus, and a distance-measuring apparatus. The light deflector includes a movable part, a pair of beams configured to make the movable part swing or oscillate, a supporting portion supporting the pair of beams, and circuitry configured to obtain information about swing or oscillation of the movable part. In the light deflector, each one of the pair of beams includes a first piezoelectric member to which a first voltage is input and a second piezoelectric member configured to generate a second voltage, and the supporting portion includes a third piezoelectric member configured to generate a third voltage. In the light deflector, the first piezoelectric member is configured to deform the pair of beams based on the first voltage to make the movable part swing or oscillate, and the circuitry is configured to obtain the information about the swing or oscillation of the movable part based on information about the second voltage and information about the third voltage. The image projection apparatus includes the light deflector, and a light source configured to emit light. In the image projection apparatus, the light emitted from the light source is deflected and projected. The distance-measuring apparatus includes the light deflector, and the light source. In the distance-measuring apparatus, the light emitted from the light source is deflected, and an object is irradiated with the light and the light reflected by the object is detected to measure distance to the object.

### BRIEF DESCRIPTION OF THE DRAWINGS

A more complete appreciation of embodiments and the many attendant advantages thereof will be readily obtained as the same becomes better understood by reference to the following detailed description when considered in connection with the accompanying drawings.

FIG. 1 is a plan view of a movable device that serves as a light deflector, according to a first embodiment of the present disclosure.

FIG. 2 is an end view of the movable device of FIG. 1 along a second axis.

FIG. 3 is an end view of the movable device of FIG. 1 cut along a P-P cut line.

FIG. 4 is a plan view of a movable device according to a modification of the first embodiment of the present disclosure.

FIG. 5 is a diagram illustrating the functions of a pair of first detection piezoelectric elements and a pair of second detection piezoelectric elements, according to an embodiment of the present disclosure.

FIG. 6 is a diagram illustrating how a first detection piezoelectric element and a second detection piezoelectric element are coupled to each other, according to an embodiment of the present disclosure.

FIG. 7 is a diagram illustrating the relation between a driving voltage and how a mirror unit swings or oscillates, according to an embodiment of the present disclosure.

FIG. 8 is a schematic circuit diagram of a differential amplifier circuit according to an embodiment of the present disclosure.

FIG. 9 is a schematic circuit diagram of an instrumented amplifier provided with a differential amplifier according to a modification of the above embodiment of the present disclosure.

FIG. 10 is a diagram illustrating a first detection signal and a second detection signal according to an embodiment of the present disclosure.

FIG. 11 is a schematic circuit diagram of a differential amplifier circuit according to a second embodiment of the present disclosure.

FIG. 12 is a schematic circuit diagram of a differential amplifier circuit and its periphery, according to a third embodiment of the present disclosure.

FIG. 13 is a schematic diagram illustrating an optical scanning system according to an embodiment of the present disclosure.

FIG. 14 is a diagram illustrating a hardware configuration of an optical scanning system according, to an embodiment of the present disclosure.

FIG. 15 is a diagram illustrating functional blocks of a control device, according to an embodiment of the present disclosure.

FIG. 16 is a flowchart of the processes performed by an optical scanning system, according to an embodiment of the present disclosure.

FIG. 17 is a schematic diagram illustrating a vehicle provided with a heads-up display according to an embodiment of the present disclosure.

FIG. 18 is a schematic diagram illustrating a heads-up display according to an embodiment of the present disclosure.

FIG. 19 is a schematic diagram illustrating an image forming apparatus provided with an optical writing device, according to an embodiment of the present disclosure.

FIG. 20 is a schematic diagram illustrating a configuration of an optical writing device according to an embodiment of the present disclosure.

FIG. 21 is a schematic diagram illustrating a vehicle provided with a light detection and ranging (LiDAR) device, according to an embodiment of the present disclosure.

FIG. 22 is another schematic diagram illustrating a vehicle provided with a LiDAR device, according to an embodiment of the present disclosure.

FIG. 23 is a schematic diagram illustrating a configuration of a LiDAR device according to embodiments of the present disclosure.

FIG. 24 is a diagram illustrating a configuration of a laser headlamp device according to an embodiment of the present disclosure.

FIG. 25 is a perspective drawing illustrating, an external appearance of a head-mounted display according to an embodiment of the present disclosure.

FIG. 26 is a diagram illustrating a configuration of a part of a head-mounted display according to an embodiment of the present disclosure.

FIG. 27 is a schematic diagram illustrating a packaged movable device, according to an embodiment of the present disclosure.

The accompanying drawings are intended to depict embodiments of the present disclosure and should not be interpreted to limit the scope thereof. The accompanying drawings are not to be considered as draw to scale unless explicitly noted.

### DETAILED DESCRIPTION

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

In describing example embodiments illustrated in the drawings, specific terminology is employed for the sake of clarity. However, the present disclosure is not intended to be limited to the specific terminology so selected and it is to be understood that each specific element includes all technical equivalents that have the same structure, operate in a similar manner, and achieve a similar result.

In the following description, illustrative embodiments will be described with reference to acts and symbolic representations of operations (e.g., in the form of flowcharts) that may be implemented as program modules or functional processes including routines, programs, objects, components, data structures, etc., that perform particular tasks or implement particular abstract data types and may be implemented using existing hardware at existing network elements or control nodes. Such existing hardware may include one or more central processing units (CPUs), digital signal processors (DSPs), application-specific integrated circuits (ASICs), field-programmable gate arrays (FPGAs), computers or the like. These terms may be collectively referred to as processors.

Unless specifically stated otherwise, or as is apparent front the discussion, terms such as “processing” or “computing” or “calculating” or “determining” or “displaying” or the like, refer to the action and processes of a computer system, or similar electronic computing, device, that manipulates and transforms data represented as physical, electronic quantities within the computer system's registers and memories into other data similarly represented as physical quantities within the computer system memories or registers or other such information storage, transmission or display devices.

Embodiments of the present disclosure are described below with reference to the accompanying drawings. In the drawings, like reference signs denote like elements, and redundant description may be omitted.

In the following description of embodiments of the present disclosure, a rotation, a swing, an oscillation, and a move may be used as a synonym for each other. Among the directions indicated by the arrows, a stacking direction of multiple layers in the piezoelectric drive circuit or the like is defined as the Z-direction, and the directions 3 o that are orthogonal to each other on a plane perpendicular to the Z-direction are defined as the X-direction and the Y-direction. The planar view refers to a view of an object in the Z-direction.

The direction that is indicated by an arrow in the X-direction is referred to as a +X-direction, and the direction opposite to the +X-direction is referred to as a −X-direction. Moreover, the direction indicated by an arrow in the +Y-direction is referred to as a +Y-direction, and the direction opposite to the +Y-direction is referred to as a −Y-direction. Further, the direction that is indicated by an arrow is referred to as a +Z-direction, and the reverse direction to the +Z-direction is referred to as a −Z-direction. However, the orientation of the light deflector is not limited by those directions, and the orientation of the light deflector may be any desired direction.

Embodiments of the present disclosure are described below under the assumption that a movable device 13 according to an embodiment of the present disclosure serves as a light deflector.

### First Embodiment

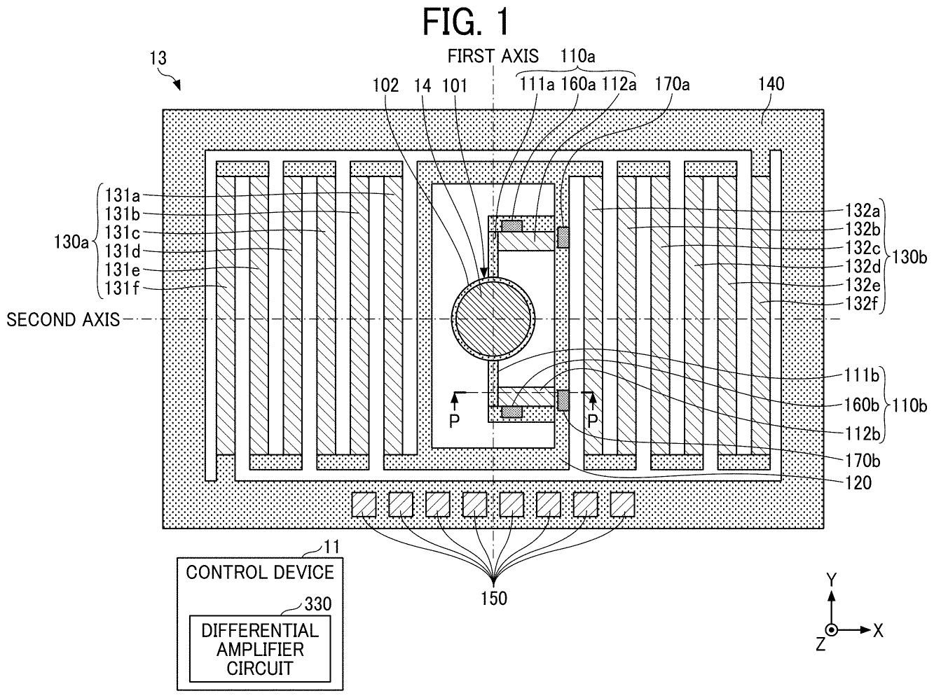

The configuration of the movable device 13 according to the first embodiment is described below with reference to FIG. 1 to FIG. 3.

FIG. 1 is a plan view of the movable device 13 according to the first embodiment of the present disclosure.

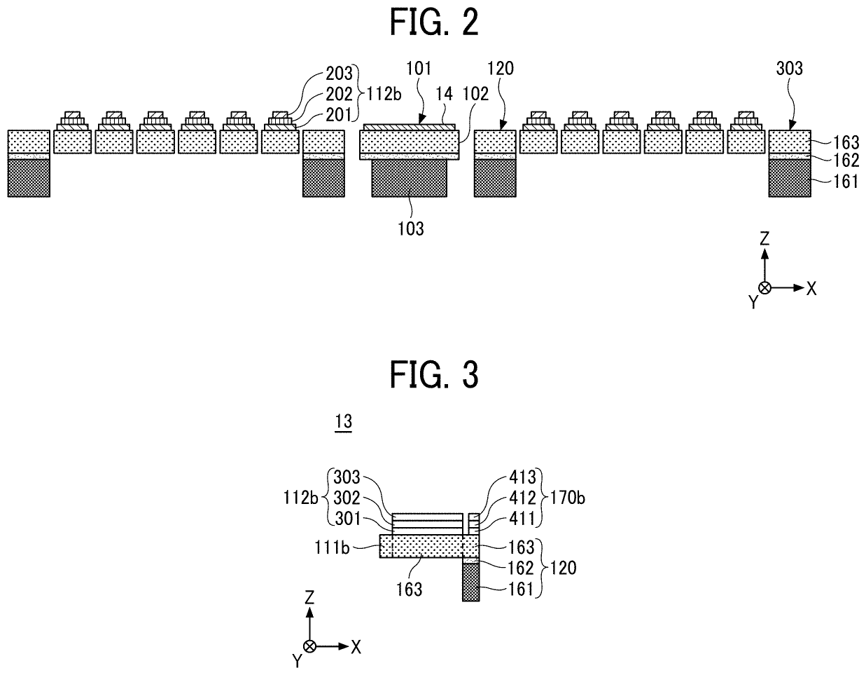

FIG. 2 is an end view of the movable device 13 of FIG. 1 along a second axis.

FIG. 3 is an end view of the movable device 13 of FIG. 1 cut along a P-P cut line.

As illustrated in FIG. 1, the movable device 13 includes a mirror unit 101, first driving units 110a and 110b, a first supporting unit 120, second driving unit 130a, a second driving unit 130b, a second supporting unit 140, a plurality of electrode connecting parts 150, and a control device 11.

The mirror unit 101 according to the present embodiment serves as a movable part that has the reflection plane 14 and reflects the incident light. Each of the first driving unit 110a and the first driving unit 110b according to the present embodiment serves as a beam that is coupled to the mirror unit 101 and makes the mirror unit 101 swing or oscillate around a first axis parallel to the Y-axis. The first supporting unit 120 according to the present embodiment serves as a supporting unit that supports the mirror unit 101, the first drive unit 110a, and the first drive unit 110b.

The second driving unit 130a and the second driving unit 130b according to the present embodiment are coupled to the first supporting unit 120, and make the mirror unit 101 and the first supporting unit 120 swing or oscillate around a second axis parallel to the X-axis. The second supporting unit 140 according to the present embodiment supports the second driving unit 130a and the second driving unit 130b. The multiple electrode connecting parts 150 are electrically connected to the first driving unit 110a, the first driving unit 110, the second driving unit 130a, the second driving unit 130b, and the control device 11.

In the movable device 13, for example, components are integrally formed as follows. On a single silicon-on-insulator (SOI) substrate, for example, the reflection plane 14, first piezoelectric drive circuits 112a and 112b, second piezoelectric drive circuits 131a to 131f and 132a to 132f, and the electrode connecting parts 150 are formed, and then the substrate is processed by etching or the like. The above-described multiple elements may be formed after the SOI substrate is molded, or may be formed while the SOI substrate is being molded.

As illustrated in FIG. 2, the SOI substrate on which the movable device 13 according to the present embodiment is formed includes a silicon supporting layer 161 made of single-crystal silicon (Si), an oxidized silicon layer 162 formed on the surface of the silicon supporting layer 161 in the +Z-direction, and a silicon active layer 163 that is made of single-crystal silicon and is formed on the oxidized silicon layer 162. The oxidized silicon layer 162 may also be referred to as a buried oxide (BOX) layer.

The silicon active layer 163 has a small thickness in the Z-axis direction compared with the X-axis direction or the Y-axis direction. Due to this configuration, a member that is made of the silicon active layer 163 serves as an elastic member.

Note also that the SOI substrate does not always have to be planar, and may have, for example, curvature. As long as the substrate can be integrally processed by etching or the like and can be partially elastic, the member used for forming the movable device 13 is not limited to the SOI substrate.

The mirror unit 101 includes, for example, a mirror-unit base 102 that has a circular shape, and the reflection plane 14 that is formed on the +Z surface of the mirror-unit base 102. The mirror-unit base 102 includes, for example, a silicon active layer 163. The reflection plane 14 includes a thin metal film made of, for example, aluminum (Al), gold (Au), and silver (Ag).

A rib 103 for strengthening the mirror unit 101 may be formed on the surface of the mirror-unit base 102 on the −Z side. The rib 103 includes, for example, the silicon supporting layer 161 and the oxidized silicon layer 162, and can prevent distortion on the reflection plane 14 caused by the movement Note that the rib 103 is not an essential element of the mirror-unit base 102.

As illustrated in FIG. 1, the first driving units 110a and 110b include two torsion bars 111a and 111b and first piezoelectric drive circuits 112a and 112b. An end of each of the torsion bars 111a and 111b is coupled to the mirror-unit base 102, and the torsion bars 111a and 111b extend in a first axis direction to support the mirror unit 101 in a movable manner. An end of each of the first piezoelectric drive circuit 112a and the first piezoelectric drive circuit 112b is coupled to a corresponding one of the torsion bars 111a and 111b, and the other end thereof is connected to an internal circumferential portion of the first supporting unit 120. The first driving unit 110a and the first driving unit 110b include the first detection piezoelectric element 160a and the first detection piezoelectric element 160b, respectively.

Each one of the first piezoelectric drive circuit 112a and the first piezoelectric drive circuit 112b according to the present embodiment serves as a first piezoelectric member to which a first voltage is applied or input. The first voltage is, for example, a driving voltage used to drive each one of the first piezoelectric drive circuit 112a and the first piezoelectric drive circuit 112b.

Each one of the first detection piezoelectric element 160a and the first detection piezoelectric element 160b according to the present embodiment serves as a second piezoelectric member that generates a second voltage. The first detection piezoelectric element 160a and the first detection piezoelectric element 160b generate, as second signals, first detection signals corresponding to the deformation caused by driving of the first driving unit 110a and the first driving unit 110b, and output the generated second detection signals.

As illustrated in FIG. 3, each one of the torsion bar 111a and the torsion bar 111b includes a silicon active layer 163. Moreover, the first piezoelectric drive circuit 112a and the first piezoelectric drive circuit 112b include the silicon active layer 163, the lower electrode 301, a piezoelectric circuit 302, and an upper electrode 303. The lower electrode 301, the piezoelectric circuit 302, and the upper electrode 303 are formed in this order on the +Z surface of the silicon active layer 163 that serves as an elastic member. For example, each of the upper electrode 303 and the lower electrode 301 includes gold (Au) or platinum (Pt). For example, the piezoelectric circuit 302 includes lead zirconate titanate (PZT) that serves as a piezoelectric material.

As illustrated in FIG. 1 to FIG. 3, the first supporting unit 120 includes a silicon supporting layer 161, an oxidized silicon layer 162, and a silicon active layer 163, and is a rectangular support formed so as to surround the mirror unit 101.

The first supporting unit 120 according to the present embodiment has the second detection piezoelectric element 170a and the second detection piezoelectric element 170b on the surface in the +Z-direction. The second detection piezoelectric elements 170a and 170b according to the present embodiment serve as the third piezoelectric members that generate a third voltage. The second detection piezoelectric element 170a and the second detection piezoelectric element 170b generate and output the second detection signals as third signals.

As illustrated in FIG. 3, the second detection piezoelectric elements 170a and 170b include the silicon active layer 163, the lower electrode 411, a piezoelectric circuit 412, and an upper electrode 413. The lower electrode 411, the piezoelectric circuit 412, and the upper electrode 413 are formed in the order listed on the surface of the silicon active layer 163 that serves as an elastic member. For example, each of the upper electrode 413 and the lower electrode 411 includes gold (Au) or platinum (P1). For example, the piezoelectric circuit 412 includes lead zirconate titanate (PZT) that serves as a piezoelectric material. The first detection piezoelectric element 160a and the first detection piezoelectric element 160b also have a configuration similar to that of the second detection piezoelectric element 170a and the second detection piezoelectric. element 170b.

As illustrated in FIG. 1, the second driving unit 130a and the second driving unit 130b include, for example, the multiple second piezoelectric drive circuits 131a to 131f and 132a to 132f that are joined so as to turn. An end of each of the second driving units 130a and 130b is coupled to a perimeter zone of the first supporting unit 120, and the other end thereof is coupled to an internal circumferential portion of the second supporting unit 140.

In the present embodiment, a connection pat of the second driving unit 130a and the first supporting unit 120 and a connection part of the second driving unit 130b and the first supporting unit 120 are in point symmetry with respect to the center of the reflection plane 14. Moreover, a connection part of the second driving unit 130a and the second supporting unit 140 and a connection part of the second driving unit 130b and the second supporting unit 140 are in point symmetry with respect to the center of the reflection plane 14.

As illustrated in FIG. 2, the second driving unit 130a and the second driving unit 130b include the silicon active layer 163, the lower electrode 201, a piezoelectric circuit 202, and an upper electrode 203. The lower electrode 201, the piezoelectric circuit 202, and the upper electrode 203 are formed in this order on the +Z surface of the silicon active layer 163 that serves as an elastic member. For example, each of the upper electrode 203 and the lower electrode 201 includes gold (Au) or platinum (Pt). For example, the piezoelectric circuit 202 includes lead zirconate titanate (PZT) that serves as a piezoelectric material.

As illustrated in FIG. 1 and FIG. 2, the second supporting unit 140 is, for example, a rectangular base including the silicon supporting layer 161, the oxidized silicon layer 162, and the silicon active layer 163, and is formed to surround the mirror unit 101, the first driving unit 110a and the first driving unit 1110b, the first supporting unit 120, and the second driving unit 130a, and the second driving unit 130b.

The multiple electrode connecting parts 150 are, for example, formed on the surface of the second supporting unit 140 and are electrically connected to each one of the upper electrode 203 and the lower electrode 201 of each of the first piezoelectric drive circuit 112a and the first piezoelectric drive circuit 112b and the second piezoelectric drive circuits 131a to 131f, and the control device 11 through electrode wiring of aluminum (Al) or the like. A signal voltage is applied to the lower electrode 201, and the upper electrode 203 is grounded (GND).

Each of the upper electrodes 203 and the lower electrodes 201 may be directly connected to the multiple electrode connecting parts 150. Alternatively, in some embodiments, the upper electrodes 203 and the lower electrodes 201 may be indirectly connected to the multiple electrode connecting parts 150 through a wire or the like that connects a pair of electrodes.

In the present embodiment, cases in which the piezoelectric circuit 202 is formed only on a surface (+Z surface) of the silicon active layer 163 that serves as an elastic member are described by way of example. However, no limitation is indicated thereby, and the piezoelectric circuit 202 may be formed on another surface (e.g., −Z surface) of the elastic member, or on both the surface and the other surface of the elastic member.

The shapes of the components are not limited to the shapes in the above embodiment of the present disclosure as long as the mirror unit 101 can be driven around the first axis or around the second axis. For example, the torsion bar 111a and the torsion bar 111b and the first piezoelectric drive circuit 112a and the first piezoelectric drive circuit 112b may have a shape with curvature.

Furthermore, an insulating layer that is formed of a silicon oxide film may be formed on at least one of the +Z surface of the upper electrode 303 of the first driving unit 110a and the first driving; unit 110b, the +Z surface of the first supporting unit 120, the +Z surface of the upper electrode 203 of the second driving units 30a and 130b, and the +Z surface of the second supporting unit 140.

In this case, electrode wiring is provided on the insulating layer, and the insulating layer is partially removed as an opening or is not formed only at a connection spot where the upper electrode 203, the upper electrode 303, the lower electrode 201, or the lower electrode 301 and the electrode wiring are coupled to each other. As a result, the first driving unit 110a, the first driving unit 110b, tile second driving unit 130a, the second driving unit 130b, and the electrode wiring can be designed with a higher degree of freedom, and furthermore, a short circuit as a result of contact between electrodes can be controlled. The silicon oxide film also has a function as an antireflection coating.

The control operation that is performed by the control device 11 to drive the first driving unit 110a and the first driving unit 110b of the movable device 13 is described below in detail.

When a positive or negative voltage is applied in a polarizing direction, the piezoelectric circuit 302 that is included in the first driving unit 110a and the first driving unit 110b and the piezoelectric circuit 202 that is included in the second driving units 130a and 130b are deformed proportionate to the potential of the applied voltage and exerts a so-called inverse piezoelectric effect. In such deformation, for example, the piezoelectric circuits expand or contract. With the above inverse piezoelectric effect, the first driving unit 110a, the first driving unit 110b, the second driving unit 130a, and the second driving unit 130b move the mirror unit 101.

In the present embodiment, the angle that the XY plane forms with the reflection plane 14 when the reflection plane 14 of the mirror unit 101 is inclined with reference to the XY plane in the αZ-direction or the −Z-direction is referred to as a deflection angle. Note also that the +Z-direction is referred to as a positive deflection angle and the −Z-direction is referred to as a negative deflection angle.

In the first driving unit 110a and the first driving unit 110b, when driving voltage is applied to the piezoelectric circuits 302 provided for the first piezoelectric drive circuit 112a and the first piezoelectric drive circuit 112b, respectively, in parallel, through the upper electrode 303 and the lower electrode 301, the piezoelectric circuit 302 is deformed.

The deformation of the piezoelectric circuit 302 acts on and causes the first piezoelectric drive circuit 112a and the first piezoelectric drive circuit 112b to be bent. As a result, through the torsion of the two torsion bar and the torsion bar 111b, driving force acts on the mirror unit 101 around the first axis, and the mirror unit 101 swings or oscillates around the first axis. The driving, voltage to be applied to the first driving unit 110a and the first driving unit 110b is controlled by the control device 11.

As the control device 11 applies driving voltage with a predetermined sine waveform to the first piezoelectric drive circuit 112a and the first piezoelectric drive circuit 112b of the first driving unit 110a and the first driving unit 110b in parallel. As a result, the mirror unit 101 can be moved around the first axis in a cycle of the driving voltage with the predetermined sine waveform.

In particular, for example, if the frequency of the driving voltage is set to about 20 kHz, which is substantially equal to a resonant frequency of the torsion bar 111a and the torsion bar 111b, using the mechanical resonance caused by the torsion of the torsion bar 111a and the torsion bar 111b, the mirror unit 101 can be resonated at about 20 kHz.

The control device 11 includes a differential amplifier circuit 330. The differential amplifier circuit 330 according to the present embodiment serves as a data acquisition unit that acquires the information about the Swing or oscillation of the mirror unit 101. The differential amplifier circuit 330 obtains the information about the swing or oscillation of the mirror unit 101 based on the information about the first detection signals output from the first detection piezoelectric element 160a and the first detection piezoelectric element 160b and the information about the second detection signals output from the second detection piezoelectric element 170a and the second detection piezoelectric element 170b.

Modification of First Embodiment

As illustrated in FIG. 1, the movable device 13 according to the present embodiment is of a cantilever type in which the first piezoelectric drive circuit 112a and the first: piezoelectric drive circuit 112b extend from the torsion bar it la and the torsion bar 111b in the +X-direction. However, the configuration or structure of the movable device 13 according to the present embodiment is not limited to the above configuration or structure as long as the mirror unit 101 can be swung or oscillated by the piezoelectric circuit 202 to which the driving voltage is applied. For example, the movable device may be of a both-end-supported type.

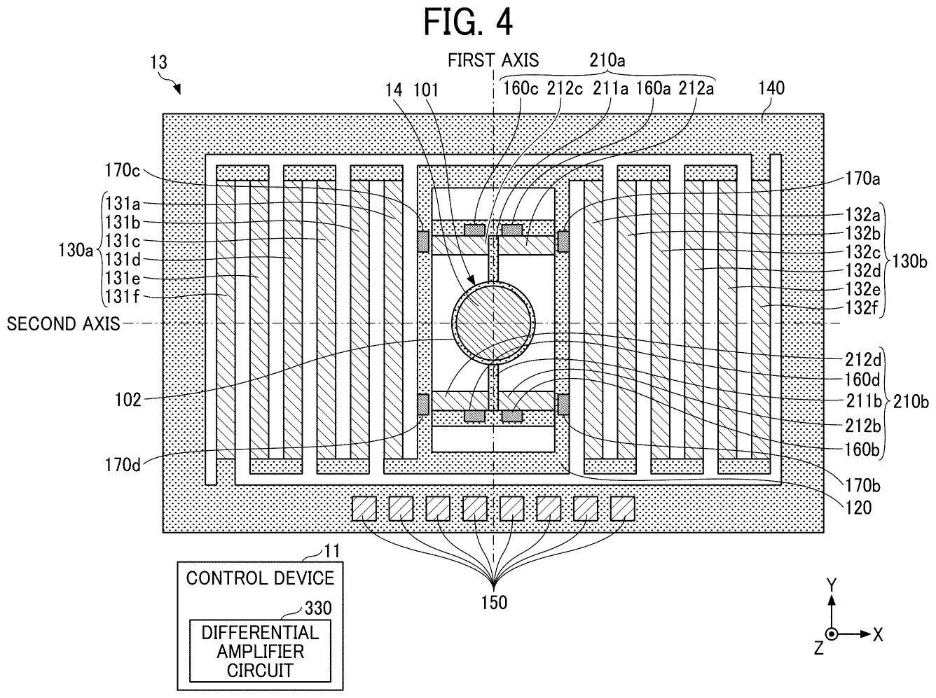

FIG. 4 is a plan view of the movable device 13a according to a modification of the first embodiment of the present disclosure.

In view of the movable device 13 according to the above embodiment of the present disclosure, like reference signs denote like elements, and redundant description may be omitted where appropriate. As illustrated in FIG. 4, the movable device 13a includes first driving units 210a and 210b.

The first driving unit 210a includes a torsion bar 211a, a first piezoelectric drive circuit 212a extending from the torsion bar 211a in the +X-direction, and a first piezoelectric drive circuit 212c. extending from the torsion bar 211a in the −X-direction.

In a similar manner to the above, the first driving unit 210b includes a torsion bar 211b, a first piezoelectric drive circuit 212b extending from the torsion bar 211b in the +X-direction, and a first piezoelectric drive circuit 212d extending from the torsion bar 211b in the −X-direction.

The embodiments of the present disclosure may be applied to the movable device 13a of such a both-side-supported type.

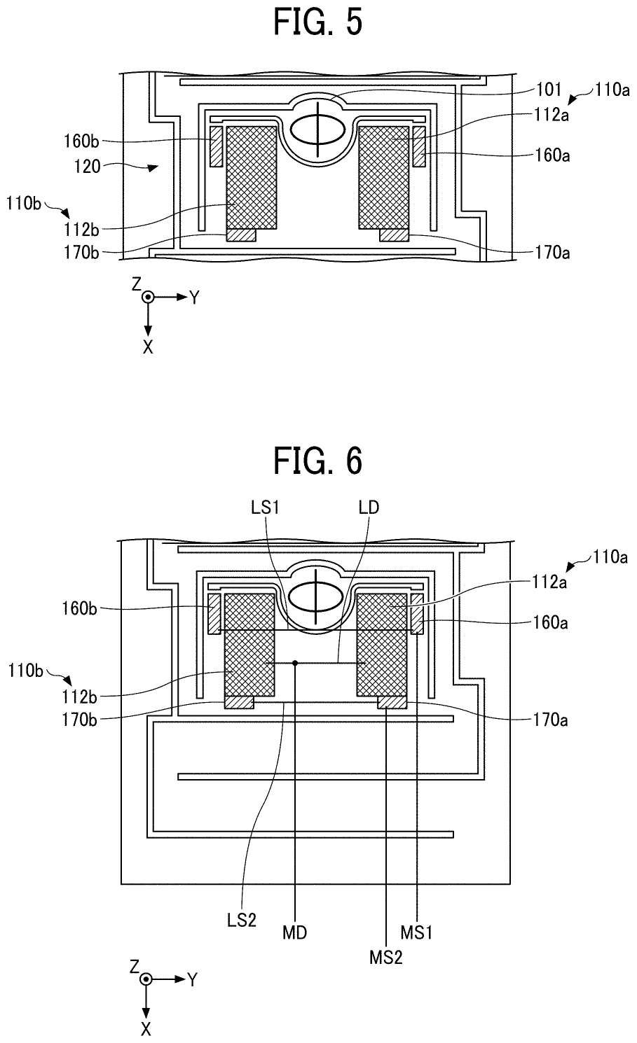

The first piezoelectric drive circuit 112a and the first piezoelectric drive circuit 112b, and the functions of the first detection piezoelectric elements 160a and 160b and the second detection piezoelectric elements 170a and 170b, according to the present embodiment, are described below with reference to FIG. 5 to FIG. 7.

FIG. 5 is a diagram illustrating the first piezoelectric drive circuit 112a and the first piezoelectric drive circuit 112b, and the functions of the first detection piezoelectric elements 160a and 160b and the second detection piezoelectric elements 170a and 170b, according to the present embodiment.

The mirror unit 101 swings or oscillates in the X-direction due to elastic defamation of the first driving unit 110a and the first driving unit 110b. As illustrated in FIG. 5, on one of both edges of the first driving unit 110a and the first driving unit 110b in the +Z-direction, a first detection piezoelectric element 160a that detects the elastic deformation of the first driving unit 110a is arranged close to a surface of the first piezoelectric drive circuit 112a in the Y-axis direction. In a similar manner to the above, a first detection piezoelectric element 160b that detects the elastic deformation of the first driving unit 110b is arranged close to the first piezoelectric drive circuit 112b.

The first piezoelectric drive circuit 112a is provided for the first driving unit 110a, and deforms the first driving unit 110a according: to the applied driving voltage. The first piezoelectric drive circuit 112b is provided for the first driving unit 110b, and deforms the first driving unit 110b according to the applied driving voltage.

The first detection piezoelectric element 160a generates first detection signals MS1out by a piezoelectric effect according to the deformation of the first driving unit 110a, and outputs the generated first detection signals MS1out to the control device 11 through the multiple electrode connecting parts 150. In a similar manner to the above, the first detection piezoelectric element 160b generates the first detection signals MS1out by a piezoelectric effect according to the deformation of the first driving unit 110b, and outputs the generated first detection signals MS1out to the control device 11 through the multiple electrode connecting parts 150.

Each one of the second detection piezoelectric element 170a and the second detection piezoelectric element 170b is disposed on the first supporting unit 120, and generates second detection signals and output the generated second detection signals to the control device 11 through the multiple electrode connecting parts 150.

In the first piezoelectric drive circuit 112a and the first piezoelectric drive circuit 112b, a driving voltage may be applied to the lower electrode 301 and the upper electrode 303 may be grounded (GND), or a driving voltage may be applied to the upper electrode 303 and the lower electrode 301 may be grounded (GND).

However, from the viewpoint of performing driving in a region where the piezoelectric characteristics, which indicate the relation between the driving voltage and the amount of deformation of the first piezoelectric drive circuit 112a and the first piezoelectric drive circuit 112b, are linear, it is desired that the driving voltage be applied to the lower electrode 301 and that the upper electrode 303 be grounded (GND). There are some cases in which an extra power source is required far negative voltage in order to apply a negative potential to the upper electrode 303. Also in this respect, it is desired that the driving voltage be applied to the lower electrode 301.

The first piezoelectric drive circuit 112a and the first piezoelectric drive circuit 112b may have a five layer structure such as a lower electrode, a piezoelectric unit, an intermediate electrode, a piezoelectric unit, and an upper electrode (203, 303, 413) in addition to a three layer structure of the lower electrode 301, the piezoelectric circuit 302, and the upper electrode 303. In a similar manner to the above, the first detection piezoelectric element 160a and the first detection piezoelectric element 160b and the second detection piezoelectric element 170a and the second detection piezoelectric element 170b may have a five layer structure such as a lower electrode, a piezoelectric circuit, an intermediate electrode, a piezoelectric circuit, and an upper electrode (203, 303, 413) in addition to the three layer structure of the lower electrode 411, the piezoelectric circuit 412, and the upper electrode 413.

In the present embodiment, in response to the application of a driving voltage to the lower electrode 301, noise may be superposed on the first detection signals MS1out output from the first detection piezoelectric element 160a and the first detection piezoelectric element 160b. This noise is, for example, crosstalk noise caused by parasitic capacitance between the silicon substrate and the lower electrode 301 of the first piezoelectric drive circuit 112a and the first piezoelectric drive circuit 112b, parasitic capacitance between the silicon substrate and the drive wiring of the first piezoelectric drive circuit 112a and the first piezoelectric drive circuit 112b, and parasitic capacitance between the output wiring of the first detection piezoelectric element 160a and the first detection piezoelectric element 160b and the silicon substrate. Crosstalk noise refers to noise that is superposed on another voltage signal due to leakage of the voltage signal into a transmission path of the other voltage signal. Crosstalk noise may also be referred to as cross noise.

As the second detection piezoelectric element 170a and the second detection piezoelectric element 170b are disposed on the first supporting unit 120 that is a stationary portion and does not deform, the second detection signals that are output from the second detection piezoelectric element 170a and the second detection piezoelectric element 170b indicate the above crosstalk noise. In the present embodiment, the second detection signals are used to remove the crosstalk noise superposed on the first detection piezoelectric element 160a and the first detection piezoelectric element 160b.

In the present embodiment, it is desired that each area of the first detection piezoelectric element 160 and the first detection piezoelectric element 160b be equal to each area of the second detection piezoelectric element 170a and the second detection piezoelectric element 170b. The term area in the present embodiment indicates an area on the XY plane of FIG. 5. The XY plane is a plane including both the first axis and the second axis in FIG. 1 or FIG. 4.

As the areas are made equal to each other as described above, the crosstalk noise that is superposed on the first detection signals by the first detection piezoelectric element 160a and the first detection piezoelectric element 160b becomes equal to the crosstalk noise that is superposed on the second detection signals by the second detection piezoelectric element 170a and the second detection piezoelectric element 170b.

The equality in area that is mentioned in the present embodiment does not require each area of the first detection piezoelectric element 160a and the first detection piezoelectric element 160b be completely equal to each area of the second detection piezoelectric element 170a and the second detection piezoelectric element 170b. A difference that is recognized as a typical error, for example, a difference of about ± 1/10 of the area, is allowed.

It is desired that the distance between the first detection piezoelectric element 160a and the first piezoelectric drive circuit 112a, the distance between the first detection piezoelectric element 160b and the first piezoelectric drive circuit 112b, the distance between the second detection piezoelectric element 170a and the first piezoelectric drive circuit 112a, the distance between the second detection piezoelectric element 170b and the first piezoelectric drive circuit 112b be equivalent to each other.

Further, it is desired that the distance between the longer side of the first detection piezoelectric element 160a and the first piezoelectric drive circuit 112a, the distance between the longer side of the first detection piezoelectric element 160b and the first piezoelectric drive circuit 112b, the distance between the longer side of the second detection piezoelectric element 170a and the first piezoelectric drive circuit 112a, and the distance between the longer side of the second detection piezoelectric element 170b and the first piezoelectric drive circuit 112b be equivalent to each other. The longer side refers to a side in the longer-side direction of a piezoelectric element having a rectangular shape in plan view.

As the distances are made equal to each other as described above, the crosstalk noise that is superposed on the first detection signals by the first detection piezoelectric element 160a and the first detection piezoelectric element 160b becomes equal to the crosstalk noise that is superposed on the second detection signals by the second detection piezoelectric element 170a and the second detection piezoelectric element 70b.

The equality in distance that is mentioned in the present embodiment does not require that the distance between the longer side of the first detection piezoelectric element 160a and the first piezoelectric drive circuit 112a, the distance between the longer side of the first detection piezoelectric element 160b and the first piezoelectric drive circuit 112b, the distance between the longer side of the second detection piezoelectric element 170a and the first piezoelectric drive circuit 112a, and the distance between the longer side of the second detection piezoelectric element 170b and the first piezoelectric drive circuit 112b are completely equal to each other. A difference that is recognized as a typical error, for example, a difference of about ± 1/10 in the length of a longer side, is allowed. This applies to the cases described below where a term “equal” or “equivalent” is used in regard to distance.

In the movable device 13, the first detection piezoelectric element 160a and the first piezoelectric drive circuit 112a make up a pair, and the first detection piezoelectric element 160b and the first piezoelectric drive circuit 112b make up a pair. Accordingly, the movable device 13 according to the present embodiment has two pairs that serve as a plurality of pairs.

FIG. 6 is a diagram illustrating how the first piezoelectric drive circuit 112a and the first piezoelectric drive circuit 112b, the first detection piezoelectric element 160a and the first detection piezoelectric element 160b, and the second detection piezoelectric element 170a and the second detection piezoelectric element 170b are electrically connected to each other, according to the present embodiment.

As illustrated in FIG. 6, the surface electrode of the first piezoelectric drive circuit 112a and the surface electrode of the first piezoelectric drive circuit 112b are coupled to a common drive input terminal MD through a drive wiring LD. The upper electrodes 303 of the first piezoelectric drive circuit 112a and the first piezoelectric drive circuit 112b are coupled to a ground line (GND).

The surface electrode of the first detection piezoelectric element 160a and the surface electrode of the first detection piezoelectric element 160b are coupled to the first detection output terminal MS1 in common through a first detection wiring LS1. The surface electrode of the second detection piezoelectric element 170a and the surface electrode of the second detection piezoelectric element 170b are coupled to the second detection output terminal MS2 in common through a first detection wiring LS2. The first detection signals that correspond to the amounts of elastic deformation detected by the first detection piezoelectric element 160a and the first detection piezoelectric element 160b are output from the first detection output terminal MS1.

The drive wiring LD, the first detection wiring LS1, and the second detection wiring LS2 are coupled to the electrode connecting part 150 through the second driving unit 130 or the second driving unit 130b as illustrated in FIG. 1.

In the present embodiment, it is desired that the drive wiring LD be arranged between the first detection wiring LS1 and the second detection wiring LS2. It is desired that the distance between the drive wiring LD and the first detection wiring LS1 be equivalent to the distance between the drive wiring LD and the second detection wiring LS2.

With such an arrangement, the parasitic capacitance between the drive wiring LD and the silicon substrate is transmitted as crosstalk noise to the output terminals MS of the first detection piezoelectric element 160a and the first detection piezoelectric element 160b, and is output.

Compared with the crosstalk noise output from the output terminal MS due to the parasitic capacitance between the silicon substrate and the lower electrodes 301 of the first piezoelectric drive circuit 112a and the first piezoelectric drive circuit 112b, the parasitic capacitance between pairs of the drive wiring LD, the first detection wiring LS1, and the second detection wiring LS2 is small. However, a driving voltage of high frequency is applied to the movable device 13, and in biaxial driving, the wiring runs through a folded structure having a plurality of folded portions and continues to the electrode connecting part 150. Accordingly, the length of wiring tends to be long. Accordingly, in order to further reduce crosstalk noise, it is desired that the crosstalk noise of an equivalent magnitude be included between the first detection wiring LS1 and the second detection wiring LS2.

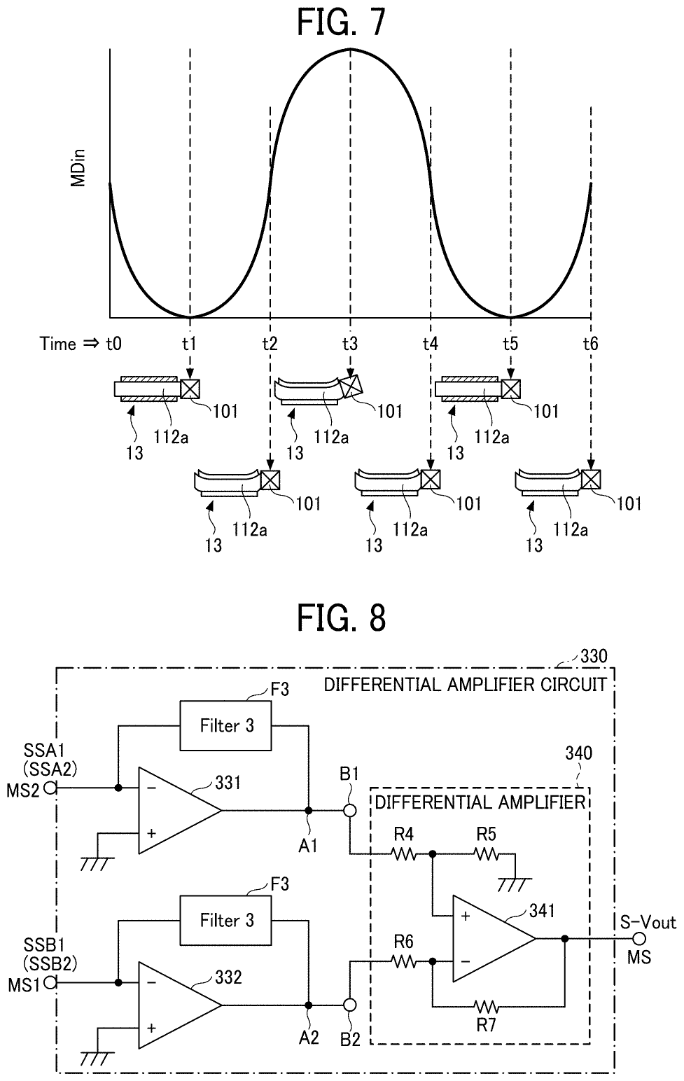

FIG. 7 is a diagram illustrating the relation between the driving voltage applied to the first piezoelectric drive circuit 112 and the first piezoelectric drive circuit 112b and how the mirror unit 101 swings or oscillates, according to the present embodiment.

Although the first piezoelectric drive circuit 112a is illustrated in FIG. 7, the same applies to the first piezoelectric drive circuit 112b.

As illustrated in FIG. 7, at a point in time t1, the driving voltage MDin is zero, and the degree of displacement, swing, or oscillation of the mirror unit 101 is zero. At the point in time t2, the first piezoelectric drive circuit 112a contracts to approximately the middle of the maximum, and the mirror unit 101 is slightly tilted to the left. At the point in time t3, the first piezoelectric drive circuit 112a is maximally contracted, and the mirror unit 101 is maximally tilted to the left.

In this manner, the mirror unit 101 is inclined in the X-direction. In other words, the mirror unit 101 swings or oscillates around the second axis parallel to the Y-direction (see FIG. 1). Preferably, the mirror unit 101 is resonantly driven in the X-direction in order to obtain a large amplitude of swing or oscillation as much as possible with a small driving power. The driving voltage Main corresponds to a driving voltage at a resonance frequency.

Subsequently, a configuration of the differential amplifier circuit 330 that is included in the control device 11 will be described with reference to FIG. 8.

FIG. 8 is a schematic circuit diagram of the differential amplifier circuit 330 according to the present embodiment.

As illustrated in FIG. 8, the differential amplifier circuit 330 according to the present embodiment includes a voltage convertor 331, a voltage convertor 332, and a differential amplifier 340.

A non-inverted input terminal of the voltage convertor 331 is grounded, and an inverted input terminal is coupled to the second detection output terminal MS2 to which the second detection signals detected by the second detection piezoelectric element 170a and the second detection piezoelectric element 170b are output through the low pass filter F3.

A non-inverted input terminal of the voltage convertor 332 is grounded, and an inverted input terminal is coupled to the first detection output terminal MS1 to which the first detection signals detected by the first detection piezoelectric element 160a and the first detection piezoelectric element 160b are output through the low pass filter F3.

The differential amplifier 340 includes an operational amplifier 341 and resistors R4 to R7. The non-inverted input terminal of the operational amplifier 341 is coupled to the output terminal of the voltage convertor 331 through the resistor R4, and the non-inverted input terminal of the operational amplifier 341 is grounded through the resistor R5.

The inverting input terminal of the operational amplifier 341 is coupled to the output terminal of the voltage convertor 332 through the resistor R6, and the inverting input terminal of the operational amplifier 341 is coupled to the output terminal MS through the resistor R7.

The magnitude of crosstalk noise that is output from each one of the first detection piezoelectric element 160a and the first detection piezoelectric element 160b is approximately equal to the magnitude of crosstalk noise that is output from each one of the second detection piezoelectric element 170a and the second detection piezoelectric element 170b. In view of these circumstances, the difference between the sum of the output power of the first detection piezoelectric element 160a and the output power of the first detection piezoelectric element 160 and the sum of the output power of the second detection piezoelectric element 170a and the output power of the second detection piezoelectric element 170b is computed by the differential amplifier circuit 330. By so doing, the crosstalk noise that is included in the first detection piezoelectric element 160a and the first detection piezoelectric element 160b can be removed. The angle of swing or oscillation can be detected with high accuracy based on the first detection signals caused by the first detection piezoelectric element 160a and the first detection piezoelectric element 160b. The angle of swing or oscillation indicates the inclination of the mirror unit 101.

Modification of Differential Amplifier 340

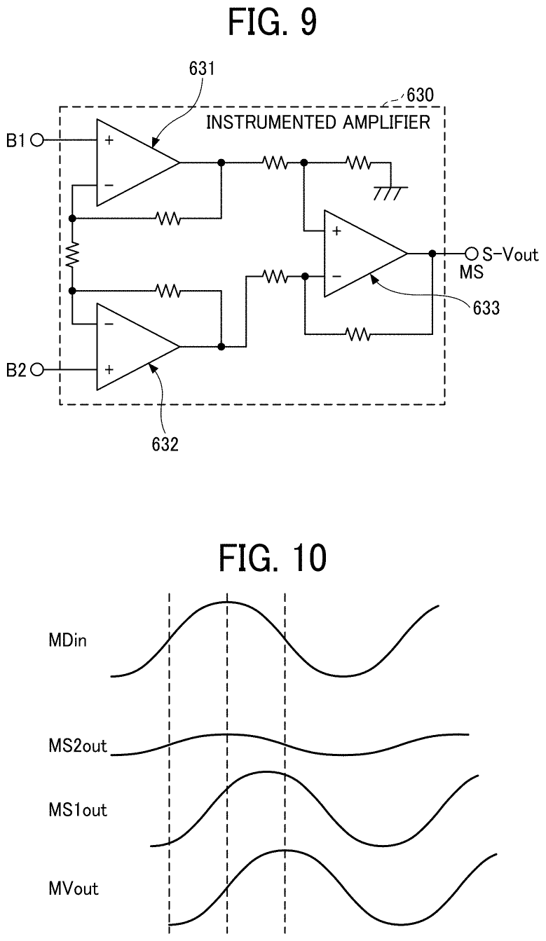

FIG. 9 is a schematic circuit diagram of an instrumented amplifier 630 provided with the differential amplifier 330 according to a modification of the above embodiment of the present disclosure.

The instrumented amplifier 630 according to the present modification of the above embodiments of the present disclosure includes, for example, an amplifiers 631, an amplifier 632, and a differential amplifier 633. If the instrumented amplifier 630 is used in place of the differential amplifier 340, the angle of swing or oscillation can be detected with higher sensitivity and even greater signal-to-noise (S/N) ratio.

Modification of Detection Piezoelectric Element

The first detection piezoelectric element 160a and the first detection piezoelectric element 160b and the second detection piezoelectric element 170a and the second detection piezoelectric element 170b are also deformable.

In the first embodiment of the present disclosure, the first detection piezoelectric element 160a and the first detection piezoelectric element 160b are provided for the first driving unit 110a and the first driving unit 110b, and are wired such that the sum of the output power of the first detection piezoelectric element 160a and the output power of the first detection piezoelectric element 160b and will be output. Moreover, the second detection piezoelectric element 170a and the second detection piezoelectric element 170b are attached to a portion of the first supporting unit 120 that does not deform, and the sum of the output power of the second detection piezoelectric element 170a and the output power of the second detection piezoelectric element 170b is subtracted from the sum of the output power of the first detection piezoelectric element 160a and the output power of the first detection piezoelectric element 160b. As a result, crosstalk noise can be removed.

By contrast, when the amount of deformation of the first driving unit 110a and the first driving unit 110b can be sufficiently detected, the crosstalk noise may be removed by computing the difference between the output signals of any one of the first detection piezoelectric element 160a and the first detection piezoelectric, element 160b and the output signals of any one of the second detection piezoelectric element 170a and the second detection piezoelectric element 170b disposed on the first supporting unit 120.

As one of the output signals of the first detection piezoelectric element 160a and the first detection piezoelectric, element 160b and one of the output signals of the second detection piezoelectric element 170a and the second detection piezoelectric element 170b are not used, these can be omitted. Alternatively, wiring fix connection can be omitted.

When the amounts of deformation of the first driving unit 110a and the first driving unit 110b cannot be sufficiently detected or when it is desired that the amounts of deformation of the first detection piezoelectric element 160 and the second detection piezoelectric element 170 be balanced, the number of pairs of the first detection piezoelectric element 160 and the second detection piezoelectric element 170 may be three or more.

FIG. 10 is a diagram illustrating a first detection signal MS1out output from the first detection piezoelectric element 160a and the first detection piezoelectric element 160b and a second detection signal MS2out output from the second detection piezoelectric element 170a and the second detection piezoelectric element 170b, according to an embodiment of the present disclosure.

In FIG. 10, the driving voltage MDin is a driving voltage input to the lower electrodes 301 of the first piezoelectric drive circuit 112a and the first piezoelectric drive circuit 112b coupled to the common drive input terminal MD through the drive wiring LD, and is a first voltage.

The second detection signal MS2out according to the present embodiment is a signal output as the surface electrode of the second detection piezoelectric element 170a and the surface electrode of the second detection piezoelectric element 170b are coupled to the second detection output terminal MS2 in common through the second detection wiring LS2, and serves as a third voltage.

The second detection signal MS2out is transmitted to the second detection output terminal MS2 through the first piezoelectric drive circuit 112a, the first piezoelectric drive circuit 112b, and the first .supporting unit 120 provided with the second detection piezoelectric element 170a and the second detection piezoelectric element 170b, and the second detection signal MS2out that indicates crosstalk noise is output from the second detection output terminal MS2.

The first detection signals MS1out according to the present embodiment is a signal output as the surface electrode of the first detection piezoelectric element 160a and the surface electrode of the first detection piezoelectric element 160b are coupled to the first detection output terminal MS1 in common through the first detection wiring LS1, and serves as a second voltage.

In addition to signals corresponding to the amounts of elastic deformation detected by the first detection piezoelectric element 160a and the first detection piezoelectric element 160b, crosstalk noise in which the driving voltage MDin is transmitted to the first detection output terminal MS1 is output. These signals are superimposed on top of one another, and the first detection signals MS1 are output from the first detection output terminal MS1out.

The detection signal MVout is an output signal obtained as the differential amplifier circuit 330 subtracts the second detection signals MS2out from the first detection signals MS1out. The magnitude of crosstalk noise that is output from each one of the first detection piezoelectric element 160a and the first detection piezoelectric element 160b is approximately equal to the magnitude of crosstalk noise that is output from each one of the second detection piezoelectric element 170a and the second detection piezoelectric element 170b. Accordingly, the crosstalk noise can be removed by subtracting the second detection signals MS2out from the first detection signals MS1out. Accordingly, the swing angle of the mirror unit 101 can be detected with high accuracy, and the swing of the mirror wait 101 can be controlled with high accuracy.

Some advantageous effects of the movable device 13 are described below.

In the related art, a configuration or structure of a movable device such as a light deflector that serves as a micro-electromechanical systems (MEMS) device is known in the art that a detection piezoelectric element that detects the amount of deformation on a pair of beams caused by the swing oscillation of a movable part is attached to the pair of beams, in addition to a piezoelectric drive circuit such as a drive piezoelectric element.

In such a configuration or structure as above, when a voltage is applied to the upper electrode (203, 303, 413) and the lower electrode of the piezoelectric drive circuit through the drive wiring, crosstalk noise may be superposed on the detection signals output from the detection piezoelectric elements due to parasitic capacitance of the pair of beams. In particular, crosstalk noise tends to occur when a driving voltage is applied to the lower electrode of the piezoelectric drive circuit. When crosstalk noise is superposed on top of one another, the accuracy of feedback control of the swing or oscillation of the movable part based on the detection signal of the detection piezoelectric element decreases.

The movable device 13 according to the present embodiment includes the mirror unit 101 that serves as a movable part, the first drive unit 110a and the first drive unit 110b that serve as a pair of beams and make the mirror unit 101 swing, or oscillate, the first supporting unit 120 that serves as a supporting unit and supports the first driving unit 110a and the first driving unit 110b, and the differential amplifier circuit 330 that serves as a data acquisition unit and obtains the information about the swing or oscillation of the mirror unit 101.

The first drive unit 110a and the first drive unit 110b according to the present embodiment includes the first piezoelectric drive circuit 112a and the first piezoelectric drive circuit 112b to which first voltage such as driving voltage MDin is input and the first detection piezoelectric element that generates the first detection signal MS1out that serves as a second voltage. The first piezoelectric drive circuit 112a and the first piezoelectric drive circuit 112b serves as the first piezoelectric member, and the first detection piezoelectric element serves as second piezoelectric member. Furthermore, the first supporting unit 120 according to the present embodiment includes a second detection piezoelectric element that serves as a third piezoelectric member and generates the second detection signal MS2out. The second detection signal MS2out serves as a third voltage.

The first piezoelectric drive circuit 112a and the first piezoelectric drive circuit 112b deform the first driving unit 110a and the first driving unit 110b based on the driving voltage MDin to swing or oscillate the mirror unit 101, and the differential amplifier circuit 330 obtains the information about the swing or oscillation of the mirror unit 101, based on the information about the first detection signal MS1out and the information about the second detection signal MS2out.

The information based on the information about the first detection signal MS1out and the information about the second detection signal MS2out is, for example, the information about a difference between the information about the first detection signal MS1out and the information about the second detection signal MS2out.

As the second detection piezoelectric element 170a and the second detection piezoelectric element 170b are disposed on the first supporting unit 120 that is a stationary portion and does not deform, the second detection signals that are output from the second detection piezoelectric element 170a and the second detection piezoelectric element 170b are signals that typically indicate the above crosstalk noise. Accordingly, as the differential amplifier circuit 330 subtracts the second detection signal MS2out from the first detection signal MS1out output from the second detection piezoelectric element 170a and the second detection piezoelectric element 170b, the crosstalk noise that is superposed on the first detection piezoelectric element 160a and the first detection piezoelectric element 160b can be removed. As a result, the information about the swing or oscillation of the mirror unit 101 can accurately be obtained.

In the present embodiment, the first piezoelectric drive circuit 112a and the first piezoelectric drive circuit 112b have an upper electrode 303, a piezoelectric circuit 302 that serves as a piezoelectric element, and a lower electrode 301, and the driving voltage MDin is applied to the lower electrode 301. When the driving voltage MDin is applied to the lower electrode 301, the linearity of piezoelectric characteristics improves. However, on the other hand, crosstalk noise more easily occurs. By removing the crosstalk noise with the application of the configuration or structure according to the present embodiment, the mirror unit 101 can be swung or oscillated with controlled crosstalk in a region where the piezoelectric characteristics have good linearity.

In the present embodiment, each area of the first detection piezoelectric element 160a and the first detection piezoelectric element 160b is equal to each area of the second detection piezoelectric element 170a and the second detection piezoelectric element 170b. Due to such a configuration, the crosstalk noise that is superposed on the first detection signals MS1out becomes equal to the crosstalk noise that is superposed on the second detection signals MS2out. Accordingly, the crosstalk noise can be removed with a high degree of accuracy by subtracting the second detection signals MS2out from the first detection signals MS1out.

In the present embodiment, the distance between the first detection piezoelectric element 160a and the first piezoelectric drive circuit 112a, the distance between the first detection piezoelectric element 160b and the first piezoelectric drive circuit 112b, the distance between the second detection piezoelectric element 170a and the first piezoelectric drive circuit 112a, and the distance between the second detection piezoelectric element 170b and the first piezoelectric drive circuit 112b are equal to each other.

Due to such a configuration, the crosstalk noise that is superposed on the first detection signals MS1out becomes equal to the crosstalk noise that is superposed on the second detection signals MS2out. Accordingly, the crosstalk noise can be removed with a high degree of accuracy by subtracting the second detection signals MS2out from the first detection signals MS1out.

in the present embodiment, the distance between the longer side of the first detection piezoelectric element 160a and the first piezoelectric drive circuit 112a, the distance between the longer side of the first detection piezoelectric element 160b and the first piezoelectric drive circuit 112b, the distance between the longer side of the second detection piezoelectric element 170a and the first piezoelectric drive circuit 112a, and the distance between the longer side of the second detection piezoelectric element 170b and the first piezoelectric drive circuit 112b are equal to each other.

Due to such a configuration, the crosstalk noise that is superposed on the first detection signals MS1out becomes equal to the crosstalk noise that is superposed on the second detection signals MS2out. Accordingly, the crosstalk noise can be removed with a high degree of accuracy by subtracting the second detection signals MS2out from the first detection signals MS1out.

In the present embodiment, two or a plurality of pairs of piezoelectric elements that are composed of the first detection piezoelectric element 160a and the first detection piezoelectric element 160b and the second detection piezoelectric element 170a and the second detection piezoelectric element 170b are provided. As a result, the signals that are output from each of the two pairs of piezoelectric elements can be amplified by adding up operation. As a result, the information about the angle of swing or oscillation of the mirror unit 101 can accurately be obtained with a desired signal-to-noise (S/N) ratio.

In the present embodiment, the drive wiring LD that inputs the driving voltage MDin to the first piezoelectric drive circuit 112a and the first piezoelectric drive circuit 112b is arranged between the first detection wiring LS1 from which the first detection signals MS1out are output and the second detection wiring LS2 from which the second detection signals MS2out are output.

Due to such a configuration, the magnitude of the parasitic capacitance components between a pair of wires of the wiring and the magnitude of the parasitic capacitance components with reference to the silicon substrate can be made equivalent to each other in the crosstalk noise. Due to such a configuration, the crosstalk noise that is superposed on the first detection signals MS1out becomes equal to the crosstalk noise that is superposed on the second detection signals MS2out. As a result, the crosstalk noise can be removed with a high degree of accuracy by subtracting the second detection signals MS2out from the first detection signals MS1out.

The configuration or structure according to the present embodiment may be applied to both the movable device 13 having the pair of beams of cantilevered structure and the movable device 13a having the pair of beams of both-end-supported structure.

### Second Embodiment

A second embodiment of the present disclosure is described below. In the second embodiment of the present disclosure, the magnitude of crosstalk noise that is included in the first detection output terminal MS1 through which the sum of the output power of the first detection piezoelectric element 160a and the output power of the first detection piezoelectric element 160b is output and the magnitude of crosstalk noise that is included in the second detection output terminal MS2 through which the sum of the output power of the second detection piezoelectric element 170a and the output power of the second detection piezoelectric element 170b is output are made equal to each other before being input to the differential amplifier 340a.

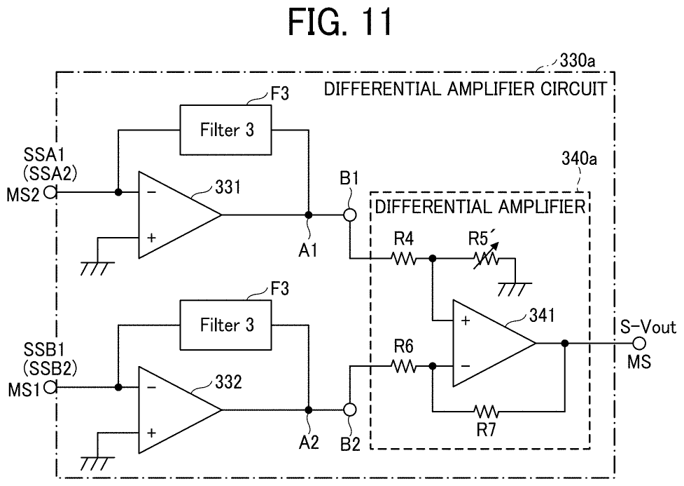

FIG. 11 is a schematic circuit diagram of a differential amplifier circuit 330a according to a second embodiment of the present disclosure.

As illustrated in FIG. 11, in the differential amplifier circuit 330a, the non-inverted input terminal of the operational amplifier 341 is coupled to the output terminal of the voltage convertor 331 through the resistor R4, and the non-inverted input terminal of the operational amplifier 341 is grounded through a variable resistor R5′. The variable resistor R5′ according to the present embodiment serves as an adjuster that adjusts the second detection signals MS2out, and is, for example, a digital potentiometer.

In the present embodiment, the magnitude of crosstalk noise that is included in the input terminal 131 of the differential amplifier 340a can be made equal to the magnitude of crosstalk noise that is included in the input terminal 132 of the differential amplifier 340a to remove the crosstalk noise by the differential amplifier circuit 330.

Due to such a configuration, even if the magnitude of crosstalk noise that is included in the first detection output terminal MS1 differs from the magnitude of crosstalk noise that is included in the second detection output terminal MS2, the magnitudes of crosstalk noise that is input to the input terminal B1 and the input terminal B2 can be made equal to each other using the variable resistor R5′.

In other words, the area of the first detection piezoelectric element 160a may be different from the area of the second detection piezoelectric element 170a, and the area of the first detection piezoelectric element 160b may be different from the area of the second detection piezoelectric element 170b. Furthermore, the distance between the first piezoelectric drive circuit 112a and the first detection piezoelectric element 160a may be different from the distance between the first piezoelectric drive circuit 112a and the second detection piezoelectric element 170a, and the distance between the first piezoelectric drive circuit 112b and the first detection piezoelectric element 160b may be different from the distance between the first piezoelectric drive circuit 112b and the second detection piezoelectric element 170b. It is desired that the second detection piezoelectric element 170a and the second detection piezoelectric element 170b are disposed at positions where crosstalk noise is output.

In regard to the arrangement of the variable resistor R.5′, for example, the frequencies of the driving voltage MDin input to the first piezoelectric drive circuit 112a and the first piezoelectric drive circuit 112b are shifted from the resonance frequencies. In such cases, the first: driving unit 110a and the first driving unit 110b do not resonate, but crosstalk noise is input from the first piezoelectric drive circuit 112a and the first piezoelectric drive circuit 112b to the first detection piezoelectric element 160a and the first detection piezoelectric element 160b and the second detection piezoelectric element 170a and the second detection piezoelectric element 170b. The variable resistor R5′ is set so as to minimize the output signal SVout of the differential amplifier 340a under the above conditions.

As other setting methods, driving voltages are applied to the second detection piezoelectric element 170a and the second detection piezoelectric element 170b [disposed on] the first supporting unit 120, and voltage signals are output from the input terminals of the first piezoelectric drive circuit 112a and the first piezoelectric drive circuit 112b. In such cases, the first driving unit 110a and the first driving unit 110b do not vibrate or oscillate, but crosstalk noise is output to the first detection piezoelectric element 160a and the first detection piezoelectric element 160b. The variable resistor R5′ is set so as to minimize the output signal SVout of the differential amplifier 340a under the above conditions.

As described above, in the present embodiment, the variable resistor R5′ that serves as an adjuster and adjusts the second detection signal MS2out that serves as a third voltage is provided, and the differential amplifier circuit 330a that serves as a data acquisition unit obtains the information about the swing or oscillation of the mirror unit 101 that serves as a movable part, based on the information about the first detection signal MS1out that serves as a second voltage and the information about the second detection signal MS2out adjusted by the variable resistor R5′.

By so doing, the magnitudes of crosstalk noise that is input to the input terminal B1 and the input terminal B2 of the differential amplifier 340a can be made equal to each other, and the difference is computed by the differential amplifier circuit 330a. As a result, crosstalk noise can be removed. As a result, the information about the swing of the mirror unit 101 can accurately be obtained.

The other aspects of the present embodiment are similar to those of the first embodiment of the present disclosure as described above.

### Third Embodiment

In the present embodiment, a storage unit that stores the voltage value of the third voltage is provided, and the data acquisition unit acquires the information about the swing or oscillation of the movable part based on the information about the second voltage and the information about the third voltage stored by the storage unit.

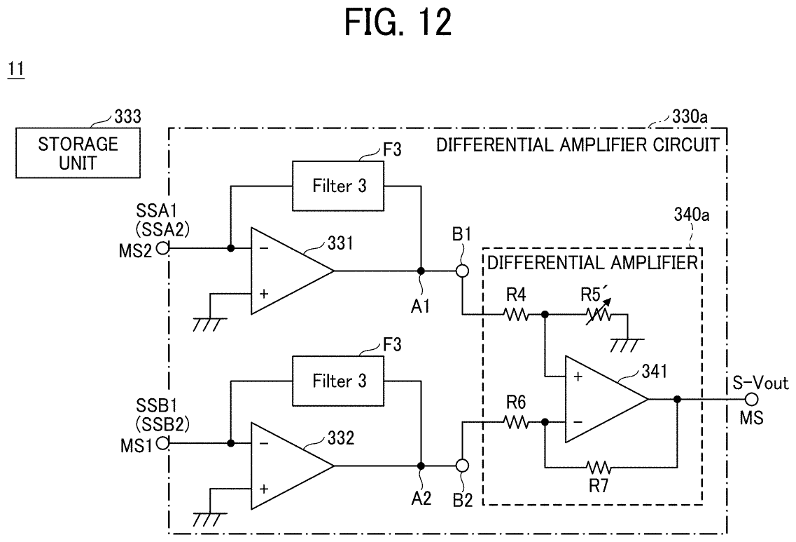

FIG. 12 is a schematic circuit diagram of a differential amplifier circuit 330a and its periphery, according to a third embodiment of the present disclosure.

The storage unit 333 is a memory that is provided for the control device 11 and is capable of storing data. The data that is stored in the storage unit 333 is equivalent to the data obtained due to the arrangement of the variable resistor R5′ described above in the second embodiment of the present disclosure.

As the data including the magnitude of crosstalk noise can be input from the storage unit 333, the variable resistor R5′ may be not provided.

As described above, in the present embodiment, the storage unit that stores the voltage value of the second detection signal MS2out that serves as a third voltage is provided, and the differential amplifier circuit 330a that serves as a data acquisition unit obtains the information about the swing or oscillation of the mirror unit 101 that serves as a movable part, based on the information about the first detection signal MS1 out that serves as a second voltage and the information about the second detection signal MS2out that serves as a third voltage and is stored in the storage unit 333.

By so doing, the magnitudes of crosstalk noise that is input to the input terminal B1 and the input terminal B2 of the differential amplifier 340a can be made equal to each other, and the difference is computed by the differential amplifier circuit 330a. As a result, crosstalk noise can be removed, and the information about the swing or oscillation of the mirror unit 101 can accurately be obtained.

The other aspects of the present embodiment are similar to those of the first embodiment of the present disclosure as described above.

### Other Embodiments

The movable device 13 according to the above-described embodiments of the present disclosure can be applied to various kinds of systems and apparatuses. A case in which the movable device 13 according to the above embodiments of the present disclosure is applied to various kinds of systems and apparatuses are described below.

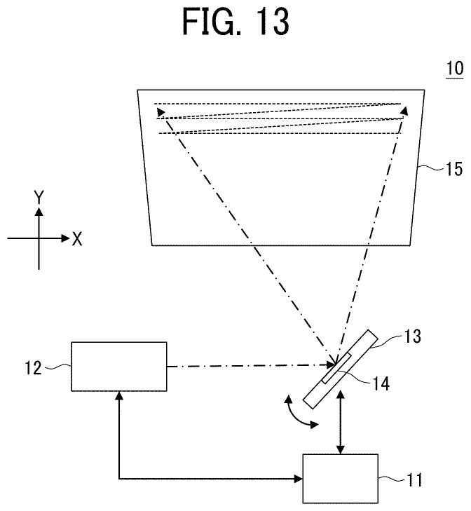

Firstly, an optical scanning system 10 to which the movable device 13 according to the above embodiments of the present disclosure is applied is described below in detail with reference to FIG. 13 to FIG. 16.

FIG. 13 is a schematic diagram illustrating the optical scanning system 10 according to an embodiment of the present disclosure.

As illustrated in FIG. 13, the optical scanning system 10 deflects light emitted from a light-source device 12 in accordance with the control of a control device 11, with a reflection plane 14 included in a movable device 13, so as to optically scan a to-be-scanned surface 15.

The optical scanning system 10 according to the present embodiment includes the control device 11, the light-source device 12, and the movable device 13 including the reflection plane 14.

For example, the control device 11 is an electronic circuit unit provided with a central processing unit (CPU) and a field-programmable gate array (FPGA). For example, the movable device 13 is provided with the reflection plane 14, and the movable device 13 serves as a micro-electromechanical systems (MEMS) device on which the reflection plane 14 can move.

For example, the light-source device 12 is a laser device that emits laser beams. For example, the to-be-scanned surface 15 according to the present embodiment is a screen.

The control device 11 generates control instructions for the light-source device 12 and the movable device 13 based on the optical scanning information obtained from an external device, and outputs a driving signal to the light-source device 12 and the movable device 13 based on the generated control instructions. The light-source device 12 causes the light source to emit light based on the received driving signal. The movable device 13 causes the reflection plane 14 to rotate and oscillate in at least one of uniaxial directions or biaxial directions, based on the received driving signal.

Due to such a configuration, for example, the reflection plane 14 of the movable device 13 can biaxially be rotated and oscillated in a reciprocating manner within a predetermined range, and the light that is emitted from the light-source device 12 to be incident on the reflection plane 14 can be deflected around a prescribed axis to perform optical scanning, under control of the control device 11, which is based on the image data according to the present embodiment that serves as the optical scanning information. Accordingly, an image can be projected onto the to-be-scanned surface 15 as desired. The movable device 13 and the control that is performed by the control device 11 according to the present embodiment will be described later in detail.

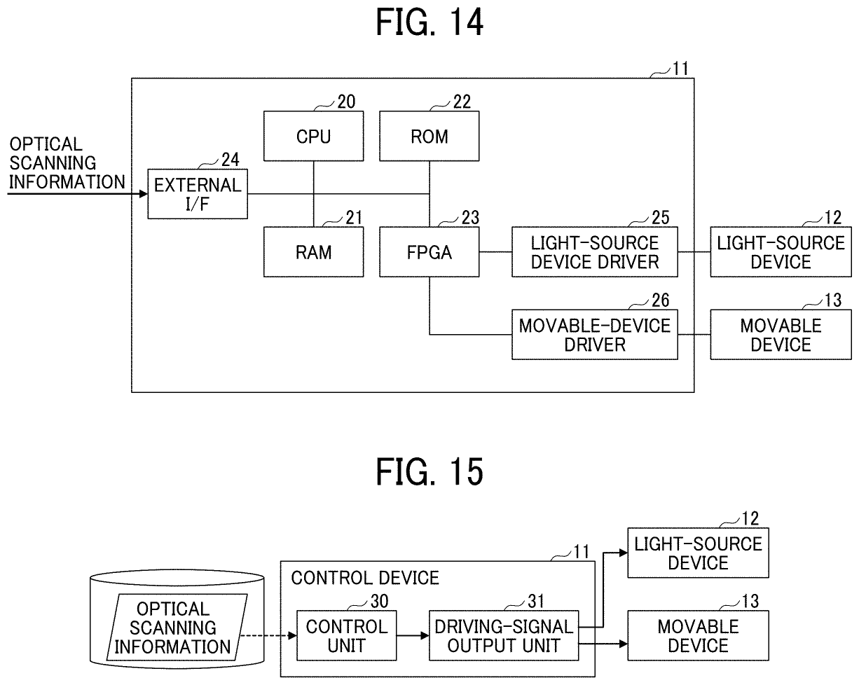

A hardware configuration of the optical scanning system 10 according to the present embodiment is described below with reference to FIG. 14.

FIG. 14 is a diagram illustrating a hardware configuration of the optical scanning system 10 according to embodiments o.f the present disclosure.

As illustrated in FIG. 14, the optical scanning system 10 includes the control device 11, the light-source device 12, and the movable device 13, which are electrically connected to each other. Among those elements, the control device 11 is provided with a central processing unit (CPU) 20, a random access memory (RAM) 21, a read only memory (ROM) 22, a field-programmable gate array (FPGA) 23, an external interface (I/F) 24, a light-source device driver 25, and a movable-device driver 26.

The CPU 20 loads into the RAM 21 a program or data from a storage device such as the ROM 22 and performs processes. Accordingly, the controls or functions of the entirety of the control device 11 are implemented.

The RAM 21 is a volatile storage device that temporarily stores data or a computer program.

The ROM 22 is a read-only nonvolatile storage device that can store a computer program or data even when the power is switched off, and stores, for example, data or a processing program that is executed by the CPU 20 to control the multiple functions of the optical scanning system 10.

The FPGA 23 is a circuit that outputs a control signal to the light-source device driver 25 and the movable-device driver 26 according to the processes performed by the CPU 20.

For example, the external interface 24 is an interface with an external device or the network. For example, the external device may be a host device such as a personal computer (PC) and a storage device such as a universal serial bus (USB) memory, a secure digital (SD) card, a compact disc (CD), a digital versatile disc (DVD), a hard disk drive (HDD), and a solid state drive (SSD). For example, the network may be a controller area network (CAN) or local area network (LAN) of a vehicle, and the Internet. The external interface 24 is satisfactory as long as it has a configuration by which connection to an external device or communication with an external device is achieved. The external interface 24 may be provided for each external device.

The light-source device driver 25 is an electric circuit that outputs a driving signal such as a driving voltage to the light-source device 12 in accordance with the received control signal.

The movable-device driver 26 is an electric circuit that outputs a driving signal such as a driving voltage to the movable device 13, in accordance with the received control signal.

In the control device 11, the CPU 20 acquires the optical scanning information from an external device or a network through the external interface 24. Note that any configuration may be used as long as the CPU 20 can acquire the optical scanning information, and the optical scanning information may be stored in the ROM 22 or in the FPGA 23 in the control device 11, or a storage device such as an SSD may be newly arranged in the control device 11 and the optical scanning information may be stored in the storage device.

The optical scanning information in the present embodiment is the information indicating how optical scanning to be performed on the to-be-scanned surface 15. For example, when an image is to be displayed by performing optical scanning, the optical scanning information is image data. For example, when optical writing is to be performed by optical scanning, the optical scanning information is writing data indicating where and in what order such optical writing is to be performed. Furthermore, for example, the optical scanning information is irradiation data indicating the timing and range of irradiation of light for object recognition when an object is to be recognized by optical scanning.

The control device 11 according to the present embodiment can implement the functional configuration described below by using commands from the CPU 20 and the hardware configuration illustrated in FIG. 14.

A functional configuration of the control device 11 of the optical scanning system 10 is described below with reference to FIG. 15.

FIG. 15 is a diagram illustrating functional blocks of the control device 11 of the optical scanning system 10, according to an embodiment of the present disclosure.

As illustrated in FIG. 15, the control device 11 has the functions of a control unit 30 and a driving-signal output unit 31.

For example, the control unit 30 is implemented by the CPU 20 or the FPGA 23, and obtains optical scanning information from an external device and converts the obtained optical scanning information into a control signal and outputs the obtained control signal to the driving-signal output unit 31. For example, the control unit 30 acquires image data from an external device or the like as the optical scanning information, generates a control signal from the image data through predetermined processing, and outputs the control signal to the drive-signal output unit 31. For example, the driving-signal output unit 31 is implemented by the light-source device driver 25 and the movable-device driver 26, and outputs a driving signal to the light-source device 12 or the movable device 13 based on the received control signal.

Note that the driving signal is a signal used to control operation of the light-source device 12 or the movable device 13. For example, the driving signal in the light-source device 12 is a driving voltage used to control the timing and intensity at which the light source emits light. Moreover, for example, the driving signal in the movable device 13 is a driving voltage used to control the timing and range of motion where the reflection plane 14 provided for the movable device 13 is moved.

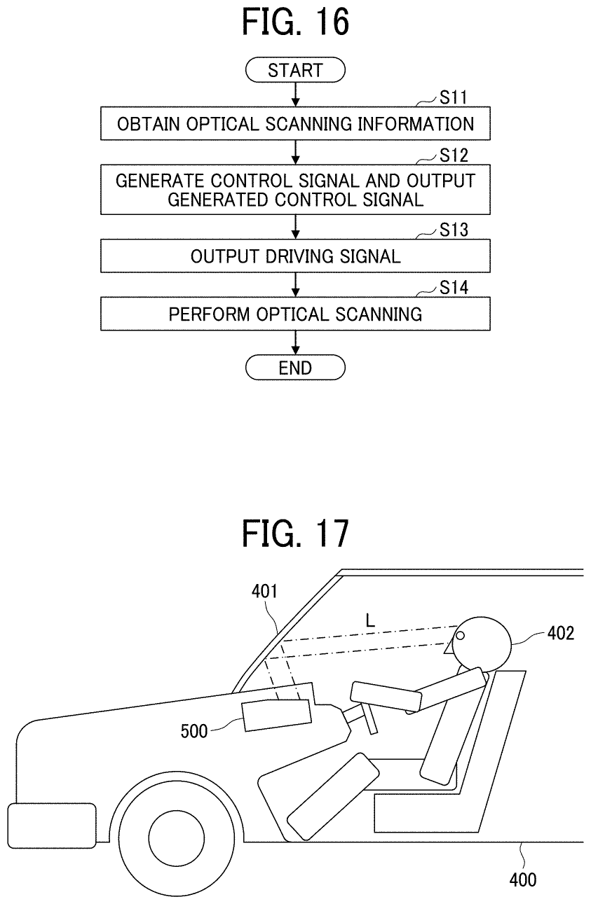

The processes of optically scanning the to-be-scanned surface 15 by the optical scanning system 10 will be described below with reference to FIG. 16

FIG. 16 is a flowchart of the processes performed by the optical scanning system 10, accordion to an embodiment of the present disclosure.

In a step S11, the control unit 30 obtains optical scanning information from, for example, an external device. In a step S12, the control unit 30 generates a control signal from the obtained optical scanning information, and outputs the generated control signal to the driving-signal output unit 31. In a step S13, the driving-signal output unit 31 outputs a driving signal to each of the light-source device 12 and the movable device 13, based on the received control signal. In a step S14, the light-source device 12 emits light based on the received driving signal. The movable device 13 according to the present embodiment causes the reflection plane 14 to rotate and oscillate, based on the received driving signal. The driving of the light-source device 12 and the movable device 13 causes light to be deflected in a given direction, and optical scanning is performed.

In the optical scanning system 10 as described above, a single control device 11 includes a device and functions used to control the light-source device 12 and the movable device 13. However, a control device for the light-source device and a control device for the movable device may separately be provided.

In the above optical scanning system 10 as described above, a single control device 11 includes functions of the control unit 30 used to control the light-source device 12 and the movable device 13, and functions oldie driving-signal output unit 31. However, these functions may separately be provided, and for example, a separate drive-signal output device with the drive-signal output unit 31 may be provided in addition to the control device 11 including the control unit 30. An optical deflection system that performs optical deflection may be configured by the control device 11 and the movable device 13 provided with the reflection plane 14, which are elements of the above optical scanning system 10.

As described above, as the movable device 13 according to the present embodiment is applied to the optical scanning system, the optical scanning system that can control the swing or oscillation of the mirror unit 101 with high accuracy and can perform optical scanning with high accuracy can be provided.

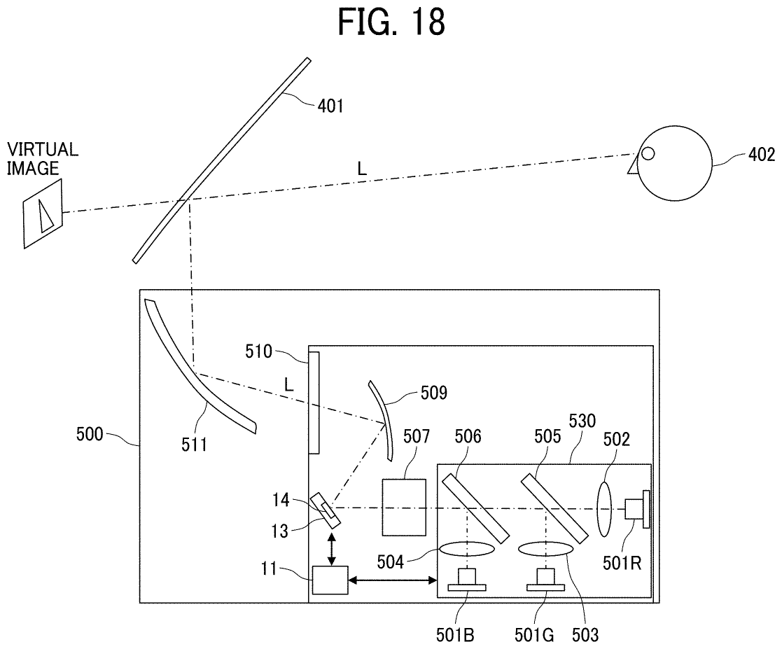

An image projection apparatus to which the movable device 13 according to the above embodiment of the present disclosure is applied is described below in detail with reference to FIG. 17 and FIG. 18.

FIG. 17 is a diagram illustrating a vehicle 400 provided with a heads-up display 500 that serves as an image projection apparatus, according to a second embodiment of the present disclosure.

FIG. 18 is a schematic diagram illustrating the heads-up display 500 according to embodiments of the present disclosure.

The vehicle 400 according to the present embodiment serves as mobile object.

The image projection apparatus is an apparatus that performs optical scanning to project an image, and is, for example, a heads-up display.

As illustrated in FIG. 17, for example, the heads-up display 500 is provided near a front windshield such as a front windshield 401 of the vehicle 400. A projection light L, which is the light for projecting an image, that is emitted from the heads-up display 500 is reflected by the front windshield 401, and is headed for a user. In the present embodiment, the user is also referred to as observer or a driver 402. Accordingly, the driver 402 can visually recognize an image or the like projected by the heads-up display 500 as a virtual image. Note that a combiner may be disposed on the inner wall of the front windshield, and the user may visually recognize a virtual image formed by the projection light L that is reflected by the combiner.

As illustrated in FIG. 18, the heads-up display 500 according to the present embodiment emits red, green, and blue laser beams from a red laser beam source 501R, a green laser beam source 501G, and a blue laser beam source 501B, respectively. The emitted laser beam passes through an incident optical system and is then deflected by the movable device 13 having the reflection plane 14. The incident optical system includes collimator lenses 502, 503, and 504, which are provided for the respective laser beam sources, two dichroic mirrors 505 and 506, and a light-intensity adjuster 507. Then, the deflected laser beams pass through a projection optical system composed of a free-form surface mirror 509, an intermediate screen 510, and a projection mirror 511, and are protected onto a screen. In the heads-up display 500 as described above, the laser beam sources 501R, 501G, and 501B, the collimator lenses 502, 503, and 504, and the dichroic mirrors 505 and 506 are unitized as a light source unit 530 in an optical housing.

The heads-up display 500 as described above projects an intermediate image that is displayed on the intermediate screen 510, on the front windshield 401 of the vehicle 400, thereby allowing the driver 402 to visually recognize the intermediate image as a virtual image.

The laser beams of the RGB colors that are emitted from the laser beam sources 501R, 501G, and 501B are approximately collimated by the collimator lenses 502, 503, and 504, respectively, and are combined by the two dichroic mirrors 505 and 506. Each of the dichroic mirror 505 and the dichroic mirror 506 according, to the present embodiment serves as a combining unit. The light intensity of the combined laser beams is adjusted by the light-intensity adjuster 507, and then two-dimensional scanning is performed by the movable device 13 provided with the reflection plane 14. The projection light L that has been two-dimensionally scanned by the movable device 13 is reflected by the free-form surface minor 509 so as to correct the distortion, and then is concentrated onto the intermediate screen 510. Accordingly, an intermediate image is displayed. The intermediate screen 510 is constituted by a microlens array in which a plurality of microlenses are two-dimensionally arranged, and expands the projected light L incident on the intermediate screen 510 in units of microlens.

The movable device 13 moves the reflection plane 14 biaxially in a reciprocating manner to perform two-dimensional scanning by using the projected light L incident on the reflection plane 14. The driving of the movable device 13 is controlled in synchronization with the light-emitting timing of the laser beam sources 501R, 501G, and 501B.

In the above embodiments of the present disclosure, the heads-up display 500 that serves as an image projection apparatus is described. However, no limitation is indicated thereby, and the image projection apparatus may be any apparatus that performs optical scanning, using the movable device 13 provided with the reflection plane 14, to project an image. For example, in a similar manner to the above, the above embodiments of the present disclosure are also applicable to a projector that is placed on a desk or the like to project an image on a display screen, a head-mounted display that is incorporated in a wearable member on the head of the observer, for example, and that projects an image on a reflective-and-transmissive screen of the wearable member or on an eve ball as a screen, and the like.

The image projection apparatus may be incorporated, not only into a vehicle or a wearable member, but also into, for example, a mobile object such as an aircraft, a ship, or a moving robot, or an immobile object such as an industrial robot that operates an object to be driven such as a manipulator without moving from the installed location.

As described above, as the movable device 13 according to the present embodiment is applied to the image projection apparatus, the image projection apparatus that can control the swing or oscillation of the mirror unit 101 with high accuracy and can perform optical scanning with high accuracy can be provided. The range of projection by the image projection apparatus can be kept constant at a desired dimension.

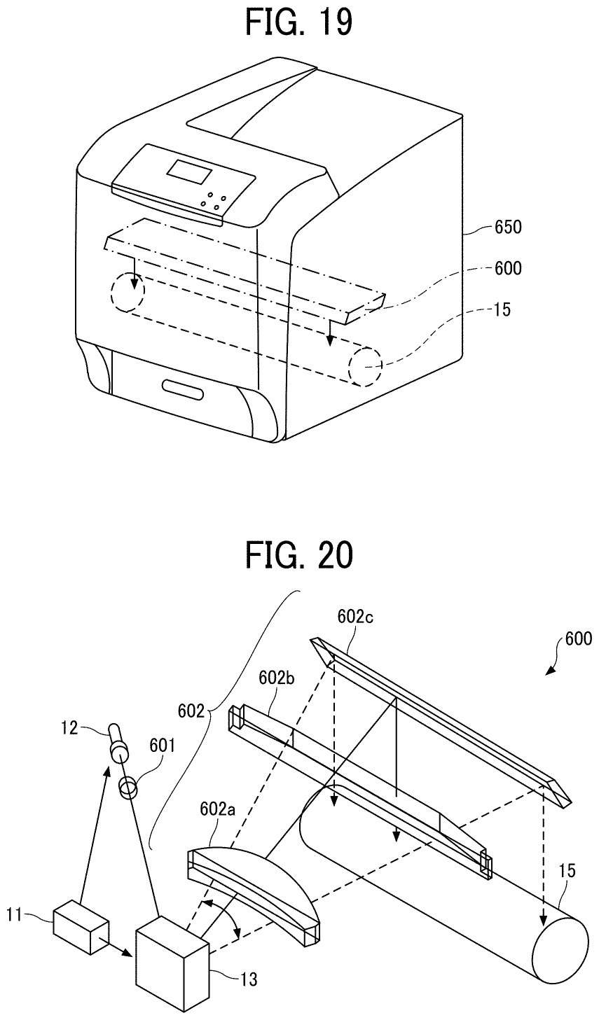

An optical writing device to which the movable device 13 according to the above embodiment is applied is described below in detail with reference to FIG. 19 and FIG. 20.

FIG. 19 is a diagram illustrating an image forming apparatus provided with an optical writing device 600, according to a third embodiment of the present disclosure.

FIG. 20 is a schematic diagram illustrating a configuration of an optical writing device 600 according to an embodiment of the present disclosure.

As illustrated in FIG. 19, the optical writing device 600 is used as a component of an image forming apparatus typified by a laser-beam printer 650 or the like. The laser-beam printer 650 serves as a primer that uses laser beams, and the optical writing device 600 in the image forming apparatus performs optical scanning on a photoconductor drum, which serves as the to-be-scanned surface 15, with one or more laser beams, to perform optical writing on the photoconductor drum.

As illustrated in FIG. 20, in the optical writing device 600, the laser beam from the light-source device 12 such as a laser element passes through an image forming optical system 601 such as a collimator lens and is then deflected uniaxially or biaxially by the movable device 13 having the reflection plane 14. Then, the laser beam that is deflected by the movable device 13 passes through a scanning optical system 602 constituted by a first lens 602a, a second lens 602b, and a reflecting mirror unit 602c, and is emitted onto the to-be-scanned surface 15 such as a photoconductor drum or photosensitive paper. By so doing, optical writing is performed. The scanning optical system 602 forms a spot-like image of the laser beams on the to-be-scanned surface 15. The movable device 13 that includes the light-source device 12 and the reflection plane 14 are driven based on the control performed by the control device 11.

As described above, the optical writing device 600 can be used as a component of an image forming apparatus that has a printing function and performs printing with a laser beam. By modifying the scanning optical system so as to enable not only uniaxial optical scanning but also biaxial optical scanning, the optical writing device 600 can also be used as a component of an image forming apparatus such as a laser labeling device that deflects laser beam to perform optical scanning on thermal media and print letters by heating.

The movable device 13 that has the reflection plane 14 to be applied to the optical writing device is advantageous in saving power for the optical writing device because the amount of power consumption to drive device is less than the amount of power consumption to drive, for example, a polygon mirror. The movable device 13 makes a smaller wind noise when the mirror substrate oscillates compared with a polygon mirror, and thus is advantageous in achieving low noise of an optical writing device. The optical writing device requires much smaller footprint than that of a polygon mirror, and the amount of heat generated by the movable device 13 is small. Accordingly, downsizing is easily achieved, and thus the optical writing device is advantageous in downsizing the image forming apparatus.

As described above, as the movable device 13 according to the present embodiment is applied to the optical writing device, the optical writing device that can control the swing or oscillation of the mirror unit 101 with high accuracy and can perform optical scanning with high accuracy can be provided.

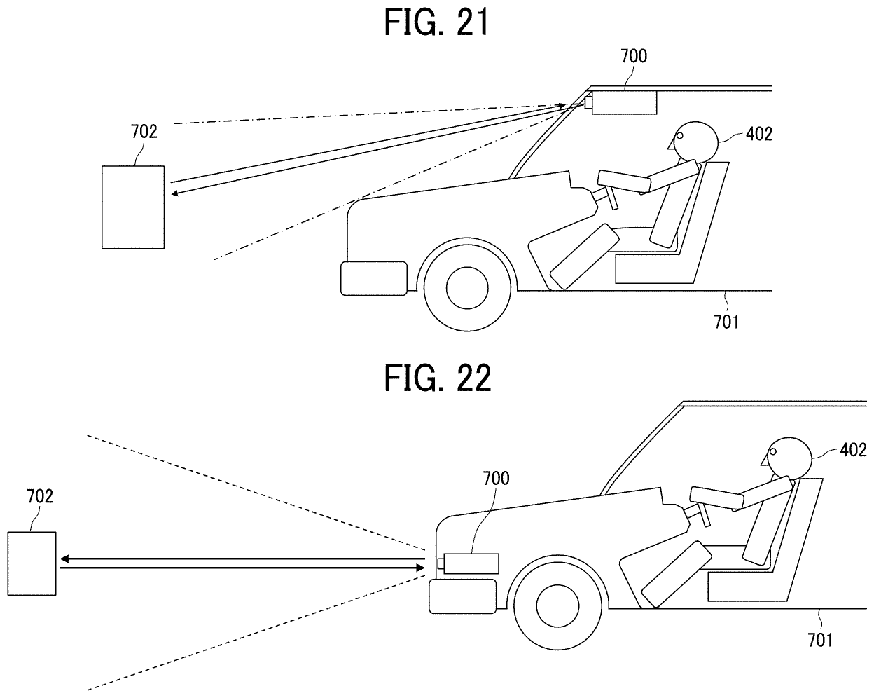

A distance-measuring apparatus that is provided with the movable device 13 according to the above embodiments of the present disclosure is described below in detail with reference to FIG. 21 to FIG. 23.

FIG. 21 and FIG. 22 are schematic diagrams of the vehicle 400 in which a light detection and ranging (LiDAR) device 700 that serves as a distance-measuring apparatus is attached to a lighting unit, according to an embodiment of the present disclosure. Typically, the lighting unit according to the present embodiment is provided with a headlight of the vehicle 400.

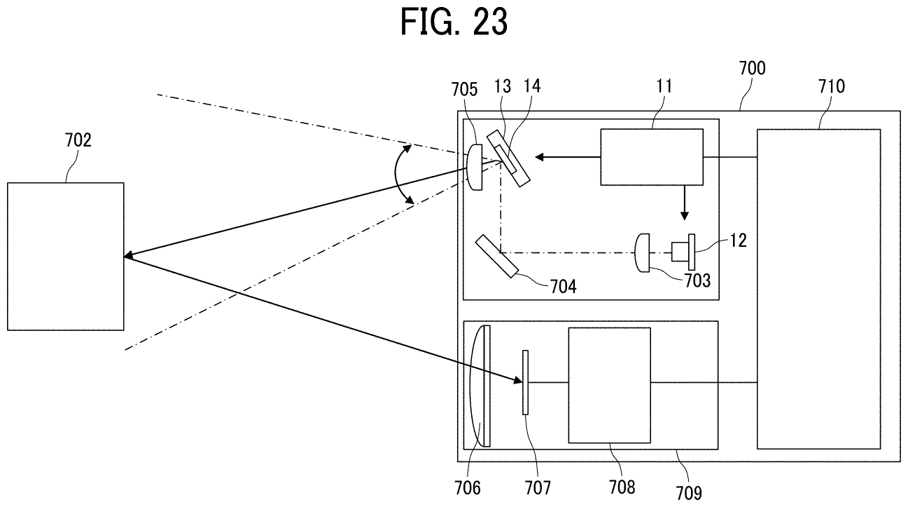

FIG. 23 is a schematic diagram illustrating a configuration of the LiDAR device 700 according to the present embodiment.

The distance-measuring apparatus according to the present embodiment is an apparatus that measures the distance to an object placed in a target direction, and is, for example, a LiDAR device.

As illustrated in FIG. 21 and FIG. 22, for example, the LiDAR device 700 is provided for a vehicle 701 to perform optical scanning in a target direction and receive the light reflected from an object 702 that exists in the target direction. Accordingly, the distance to the object 702 can be measured. The vehicle 701 according, to the present embodiment serves as mobile object.

As illustrated in FIG. 23, the laser beam that is emitted from the light-source device 12 passes through an incident optical system constituted by a collimator lens 703, which is an optical system approximately collimating diverging light, and a plane mirror 704, and then is uniaxially or biaxially scanned by the movable device 13 provided with the reflection plane 14. Then, the laser beam is emitted to the object 702 ahead of the LiDAR device 700, as passing through, for example, a projection lens 705 that serves as a projection optical system. The operation of the light-source device 12 and the movable device 13 is controlled by the control device 11. The light that is reflected by the object 702 is detected by a photodetector 709. In other words, the reflected light passes through, for example, a condenser lens 706 that serves as an incident-fight detective and light-receptive optical system, and is received by an imaging device 707. Then, the imaging device 707 outputs a detected signal to a signal processing unit 708. The signal processing unit 708 performs predetermined processing on the input detected signal, such as binarization or noise processing, and outputs the result to a distance measuring circuit 710.

The distance measuring circuit 710 determines whether the object 702 is present based on the time difference between the timing at which the light-source device 12 emits laser beam and the timing at which the photodetector 709 receives the laser beam or the phase difference among pixels of the imaging device 707 that receives light, and calculates the distance to the object 702.

The movable device 13 that is provided with the reflection plane 14 cannot easily be broken and is compact compared with a polygon mirror, and thus, a highly durable and compact LiDAR device can be provided. Such a LiDAR device is attached to, for example, a vehicle, an aircraft, a ship, a robot, or the like, and can perform optical scanning within a predetermined range to determine whether an obstacle is present or to measure the distance to the obstacle.

In the above description of the distance-measuring apparatus, the LiDAR device 700 according to the above embodiment of the present disclosure is referred to. However, no limitation is intended thereby. The distance-measuring apparatus may be any apparatus that performs optical scanning by controlling the movable device 13 provided with the reflection plane 14, using the control device 11, and that receives the receives the reflected laser beam using a photodetector to measure the distance to the object 702.

For example, in a similar manner to the above, the above embodiments of the present disclosure are also applicable to a biometric authentication apparatus, a security sensor, or a component of a three-dimensional scanner, for example. The biometric authentication apparatus performs optical scanning on a hand or face to obtain distance information, calculates object information such as the shape of the object based on the distance information, and refers to records to recognize the object. The security sensor performs optical scanning in a target range to recognize an incoming object. The three-dimensional scanner performs optical scanning to obtain distance information, calculates object information such as the shape of the object based on the distance information to recognize the object, and outputs the object information in the form of three-dimensional data.

As described above, as the movable device 13 according to the present embodiment is applied to the distance-measuring apparatus, the distance-measuring apparatus that can control the swing or oscillation of the minor unit 101 with high accuracy and can perform optical scanning with high accuracy can be provided. The measuring range by the distance-measuring apparatus can be kept constant at a desired dimension.

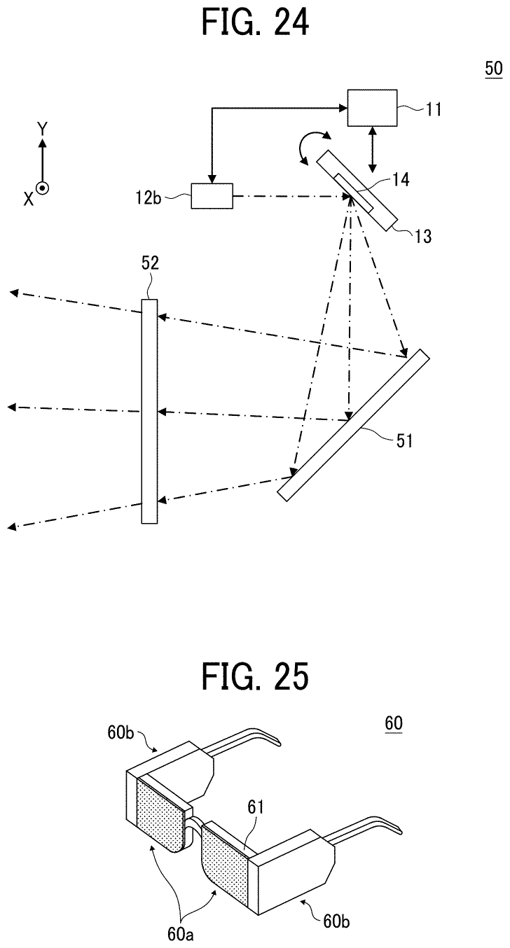

A laser headlamp 50 in which the movable device 13 according to the above embodiments of the present disclosure is used as a headlight of a vehicle is described below in detail with reference to FIG. 24.

FIG. 24 is a diagram illustrating a configuration of the laser headlamp 50 according to the present embodiment.

The laser headlamp 50 includes the control device 11, the light-source device 12, the movable device 13 provided with the reflection plane 14, a mirror 51, and a transparent plate 52.

The light-source device 12b is a light source that emits blue laser beams. The laser beams that are emitted from the light-source device 12b are incident on the movable device 13, and are reflected by the reflection plane 14. The movable device 13 drives the reflection plane in the XY-directions based on a signal sent from the control device 11, and two-dimensionally scans the blue laser beams emitted from the light-source device 12b.

The scanning light of the movable device 13 is reflected by the mirror 51, and is incident on the transparent plate 52. The transparent plate 52 is coated with a fluorescent material whose surface or back side is in yellow. The blue laser beams that are reflected by the mirror 51 are converted and changed into white laser beams, where the range of white color is legally prescribed as the color of a headlight, as passing through the coating of the yellow fluorescent material of the transparent plate 52. Due to this configuration, the sight ahead of the vehicle is illuminated with the white illumination light that has passed through the transparent plate 52.

The scanning light of the movable device 13 scatters at a predetermined degree as passing through the fluorescent material of the transparent plate 52. Due to this configuration, glare is attenuated at an illuminated target in the area ahead of the vehicle.

When the movable device 13 is applied to the headlights of the vehicle, the colors of the light-source device 121 and the fluorescent material are not limited to blue and yellow, respectively. For example, the light-source device 12b may emit near-ultraviolet light, and the transparent plate 52 may be coated with homogenized mixture of a plurality of kinds of fluorescent materials of red-green-blue (RGB) trichromatic colors. Also in such a configuration as above, the light that passes through the transparent plate 52 can be converted into white light, and the sight ahead of the vehicle can be irradiated with white light.

As described above, as the movable device 13 according to the present embodiment is applied to the laser headlamp device, the laser headlamp device that can control the swing or oscillation of the mirror unit 101 with high accuracy and can perform optical scanning with high accuracy can be provided.

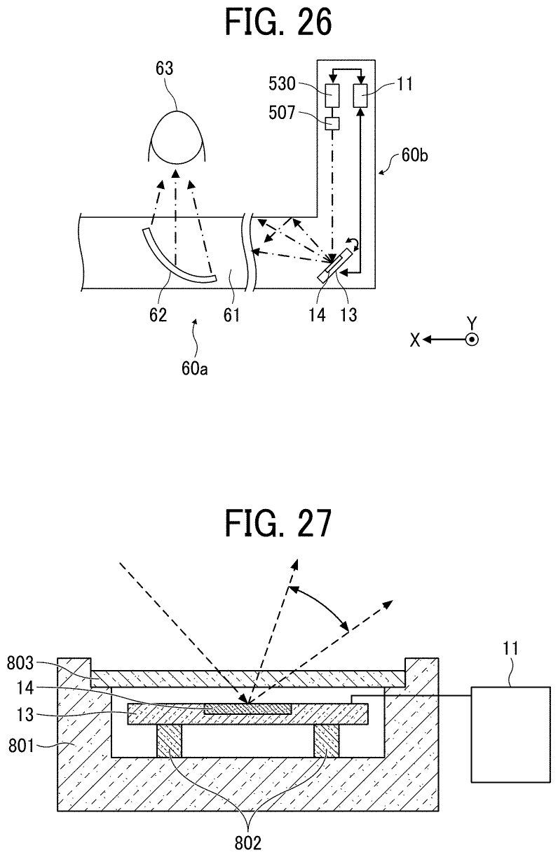

A head-mounted display 60 to which the movable device 13 according to the above embodiment of the present disclosure is applied is described below in detail with reference to FIG. 25 and FIG. 26. In the present embodiment, the head-mounted display 60 is a display that is mountable onto a human head. For example, the head-mounted display 60 may be shaped like glasses. In the following description, such a head-mounted display may be referred to simply as an HMD.

FIG. 25 is a perspective view of the HMD 60 illustrating its external appearance, according to the present embodiment.

In FIG. 25, the HMD 60 includes a pair of right and left front parts 60a and temples 60b that are approximately symmetrically arranged. For example, each of the pair of front parts 60a may be configured by a light guide plate 61, and an optical system or control device may be incorporated into at least one of the temples 60b.

FIG. 26 is a partial view of a configuration of the HMD 60, according to the present embodiment.

In FIG. 26, a configuration or structure for the left eye is illustrated.

However, no limitation is indicated thereby, and the HMD 60 may have a similar configuration or structure on the other side for the right eye.

The HMD 60 includes the control device 11, a light source unit 530, a light-intensity adjuster 507, the movable device 13 provided with the reflection plane 14, the light guide plate 61, and a half mirror 62.

As described above, the light source unit 530 according to the present embodiment includes the laser beam sources 501R, 501G, and 501B, the collimator lenses 502, 503, and 504, and the dichroic mirrors 505 and 506, and these elements are unitized by an optical housing. In the light source unit 530, the laser beams of three colors that are emitted from the laser beam sources 501R, 501G, and 501B are combined by the dichroic mirrors 505 and 506. The combined parallel light is emitted from the light source unit 530.

The light is emitted from the light source unit 530, and the light-intensity adjuster 507 adjusts the intensity of light. Then, the light whose intensity has been adjusted is incident on the movable device 13. The movable device 13 drives the reflection plane 14 in the XY-directions based on a signal sent from the control device 11, and two-dimensionally scans the light emitted from the light source unit 530. The driving of the movable device 13 is controlled in synchronization with the light-emitting timing of the laser beam sources 501R. 501G, and 501B, and a color image is formed by the scanning light.

The scanning light of the movable device 13 is incident on the light guide plate 61. The light guide plate 61 reflects the scanning light on the inner wall, and guides the scanning light to the half mirror 62. The light guide plate 61 is formed by, for example, resin that has transparency to the wavelength of the scanning light.

The half mirror 62 reflects the light that is guided through the light guide plate 61 to the rear side of the HMD 60, and the reflected light exits toward an eye of a wearer 63 of the HMD 60. For example, the half mirror 62 may have a free-form curved surface. The scanning light is reflected by the half mirror 62, and the image is formed on the retina of wearer 63. Alternatively, the image is formed on the retina of wearer 63 due to the reflection by the half mirror 62 and the lens effect of the crystalline lens of the eye. The spatial distortion on the image is corrected due to the reflection by the half mirror 62. The wearer 63 can observe an image formed by the light that is scanned in the XY-directions.

As the half mirror 62 serves as a half mirror, the wearer 63 observes both an linage formed by extraneous light and an image formed by scanning light in an overlapping manner. The half mirror 62 may be replaced with a mirror to exclude the extraneous light. In such a configuration, only the image that is formed by scanning light can be observed.

As described above, as the movable device 13 according to the present embodiment is applied to the head-mounted display, the bead-mounted display that can control the swing or oscillation of the mirror unit 101 with high accuracy and can perform optical scanning with high accuracy can be provided.

The movable device that is packaged, according to the present embodiment, is described below with reference to FIG. 27.

FIG. 27 is a schematic diagram illustrating the movable device 13 that is packaged, according to an embodiment of the present disclosure.

As illustrated in FIG. 27, the movable device 13 is attached to an attaching component 802 arranged inside the package 801, and is hermetically sealed and packaged as part of the package 801 is covered with a light transmission member 803. Further, inert gas such as nitrogen is hermetically sealed inside the package. Due to this configuration, deterioration due to oxidization can be prevented in the movable device 13, and durability against changes in the environment such as temperature can further be improved.

The above-described embodiments are illustrative and do not limit the present disclosure. Thus, numerous additional modifications and variations are possible in light of the above teachings. For example, elements and/or features of different illustrative embodiments may be combined with each other and/or substituted for each other within the scope of the present disclosure.

In the above-described embodiments of the present disclosure, a configuration or structure in which the movable part is provided with a reflection plane is described. However, no limitation is intended thereby, and the movable part according to the above embodiments of the present disclosure may include other optical elements such as a diffraction grating, a photodiode (PD), a heating device such as a heater that uses a silicon mononitride (SiN), and a light source such as a surface-emitting laser device. Alternatively, the movable part according to the above embodiments of the present disclosure may include both a reflection plane and other optical elements.

Any one of the above-described operations may be performed in various other ways, for example, in an order different from the one described above.

Each of die functions of the described embodiments may be implemented by one or more processing circuits or circuitry. Processing circuitry includes a programmed processor, as a processor includes circuitry. A processing circuit also includes devices such as an application specific integrated circuit (ASIC), digital signal processor (DSP), field programmable gate array (FPGA), and conventional circuit components arranged to perform the recited functions.

What is claimed is:

1. A light deflector comprising:
a movable part;
a pair of beams configured to make the movable part swing or oscillate;
a supporting portion supporting the pair of beams; and
circuitry configured to obtain information about swing or oscillation of the movable part,
wherein each one of the pair of beams includes a first piezoelectric member to which a first voltage is input and a second piezoelectric member configured to generate a second voltage,
wherein the supporting portion includes a third piezoelectric member configured to generate a third voltage,
wherein the first piezoelectric member is configured to deform the pair of beams based on the first voltage to make the movable part swing or oscillate, and
wherein the circuitry is configured to obtain the information about the swing or oscillation of the movable part based on information about the second voltage and information about the third voltage.

2. The light deflector according to claim 1,
wherein the circuitry is configured to obtain information about swing or oscillation of the movable part based on a difference between the second voltage and the third voltage.

3. The light deflector according to claim 1,
wherein the first piezoelectric member includes an upper electrode (203, 303, 413), a piezoelectric clement, and a lower electrode, and
wherein the first voltage is applied to the lower electrode.

4. The light deflector according to claim 1,
wherein the second piezoelectric member has an area equal to an area of the third piezoelectric member.

5. The light deflector according to claim 1,
wherein a distance between the second piezoelectric member and the first piezoelectric member is equal to a distance between the third piezoelectric member and the first piezoelectric member.

6. The light deflector according to claim 1,
wherein a distance between a longer side of the second piezoelectric member and the first piezoelectric member is equal to a distance between a longer side of the third piezoelectric member and the first piezoelectric member.

7. The light deflector according to claim 1, further comprising
a plurality of pairs of piezoelectric members, each one of the plurality of pairs of piezoelectric members being composed of the second piezoelectric member and the third piezoelectric member.

8. The light deflector according to claim 1, further comprising
a wiring through which a driving voltage is input to the first piezoelectric member between a first wiring (LS1) from which the second voltage is output and a second wiring (LS2) from which the third voltage is output.

9. The light deflector according to claim 1, further comprising
an adjuster configured to adjust the third voltage,
wherein the circuitry is configured to obtain the information about the swing or oscillation of the movable part based on the information about the second voltage and information about the third voltage adjusted by the adjuster.

10. The light deflector according to claim 1, further comprising
a memory configured to store a voltage value of the third voltage,
wherein the circuitry is configured to obtain the information about the swing or oscillation of the movable part based oh the information about the second voltage and information about the third voltage stored in the memory.

11. The light deflector according to claim 1,
wherein the pair of beams has a structure of a cantilever.

12. The light deflector according to claim 1,
wherein the pair of beams has a both-end-supported structure.

13. An image projection apparatus comprising:
a light deflector including
a movable part,
a pair of beams configured to make the movable part swing or oscillate,
a supporting portion supporting the pair of beams, and
circuitry configured to obtain information about swing or oscillation of the movable part; and
a light source configured to emit light,
wherein each one of the pair of beams includes a first piezoelectric member to which a first voltage is input and a second piezoelectric member configured to generate a second voltage,
wherein the supporting portion includes a third piezoelectric member configured to generate a third voltage,
wherein the first piezoelectric member is configured to deform the pair of beams based on the first voltage to make the movable part swing or oscillate,
wherein the circuitry is configured to obtain the information about the swing or oscillation of the movable part based on information about the second voltage and information about the third voltage, and
wherein the light emitted from the light source is deflected and projected.

14. The linage projection apparatus according to claim 13, further comprising:
a plurality of light sources including the light source, the plurality of light sources being configured to emit a plurality of lights of different wavelengths; and
a combining unit configured to combine the plurality of lights emitted from the plurality of light sources,
wherein the plurality of lights emitted from the combining unit are deflected and projected.

15. A heads-up display comprising:
the light deflector according to claim 1.

16. A laser headlamp comprising
the light deflector according to claim 1.

17. A head-mounted display comprising
the light deflector according to claim 1.

18. A distance-measuring apparatus comprising:
a light deflector including
a movable part,
a pair of beams configured to make the movable part swing or oscillate,
a supporting portion supporting the pair of beams, and
circuitry configured to obtain information about swing or oscillation of the movable part; and
a light source configured to emit light,
wherein each one of the pair of beams includes a first piezoelectric member to which a first voltage is input and a second piezoelectric member configured to generate a second voltage,
wherein the supporting portion includes a third piezoelectric member configured to generate a third voltage,
wherein the first piezoelectric member is configured to deform the pair of beams based on the first voltage to make the movable part swing or oscillate,
wherein the circuitry is configured to obtain the information about the swing or oscillation of the movable part based on information about the second voltage and information about the third voltage,
wherein the light emitted from the light source is deflected, and
wherein an object is irradiated with the light, and the light reflected by the object is detected, to measure distance to the object.

19. A mobile object comprising the heads-up display according to claim 15.

20. A mobile object comprising the laser headlamp according to claim 16.
